(19) United States
(12) Patent Application Publication
(10) Pub. No.: US 2026/0334058 A1
(43) Pub. Date: Oct. 22, 2026

(54) SUPPORT FILM, DISPLAY DEVICE INCLUDING THE SAME, ELECTRONIC DEVICE INCLUDING THE SAME, AND METHOD FOR PROVIDING THE SAME

(71) Applicant: Samsung Display Co., LTD., Yongin-si (KR)

(72) Inventors: Jae Lok CHA, Yongin-si (KR); Hyung Woo KWON, Yongin-si (KR); Won Chul LEE, Yongin-si (KR); Mun Sik HAM, Yongin-si (KR)

(21) Appl. No.: 19/560,212

(22) Filed: Mar. 9, 2026

(30) Foreign Application Priority Data
Apr. 22, 2025 (KR) 10-2025-0052655
Oct. 14, 2025 (KR) 10-2025-0147809

(51) Int. Cl. H10K 59/80; H10K 59/12

(52) U.S. Cl. CPC H10K 59/873; H10K 59/1201

(57) ABSTRACT

An electronic device includes a display panel having a display area, a bending area, and a non-display area between the display area and the bending area, a support layer facing the display panel, and a first coupling member which is between the display panel and the support layer and couples the display panel to the support layer. The support layer includes a structural layer, a resin layer surrounding the structural layer, a side of the support layer overlaps the non-display area which is between the display area and the bending area, and a portion of the side which corresponds to the bending area defining a protruding portion or a concave portion which is spaced apart from the bending area.

This application claims priority to Korean Patent Application Nos. 10-2025-0052655 filed on Apr. 22, 2025 and 10-2025-0147809 filed on Oct. 14, 2025, and all the benefits accruing therefrom under 35 U.S.C. § 119, the disclosure of which is incorporated herein by reference in its entirety.

### BACKGROUND

### 1. Field

The present disclosure relates to a support film, a display device including the same, a method for fabricating (or providing) the same, and an electronic device including a display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices include an organic light-emitting display device including organic light-emitting elements, an inorganic light-emitting display device including inorganic light-emitting elements such as inorganic semiconductor, and a micro light-emitting display device including micro light-emitting elements.

### SUMMARY

Aspects of the present disclosure provide a support film which can address bending defects of a display panel, a display device including the same, a method for fabricating (or providing) a display device, and an electronic device including a display device.

It should be noted that objects of the present disclosure are not limited to the above-mentioned object, and other objects of the present disclosure will be apparent to those skilled in the art from the following descriptions.

According to an embodiment of the present disclosure, a support film includes a support layer including a structural layer and a resin layer surrounding the structural layer, a first release film located on the support layer, a second release film located under the support layer, a first coupling member located between the support layer and the first release film, and a second coupling member located between the support layer and the second release film, where the support film includes a concave groove on at least one side.

In an embodiment, the structural layer includes a metal, ultra-thin glass or hybrid thin film glass.

In an embodiment, the resin layer surrounds a lower surface and a side surface of the structural layer.

In an embodiment, an upper surface of the structural layer and an upper surface of the resin layer are located on a same plane.

In an embodiment, the groove is located in the resin layer, the first release film, the second release film, the first coupling member and the second coupling member, and is spaced apart from the structural layer in a plan view.

In an embodiment, the resin layer overlaps with the structural layer, and a thickness of a portion of the resin layer which does not overlap with the structural layer is larger than a thickness of the structural layer.

According to an embodiment of the present disclosure, a display device includes a display panel including a display area, a non-display area and a bending area, a support layer located under the display panel, and a first coupling member located between the display panel and the support layer, where the support layer includes, a structural layer, a resin layer surrounding the structural layer, and a protruding portion or a groove located on one side of the resin layer, and a protruding surface of the protruding portion or a concave surface of the groove is spaced apart from the bending area toward the display area in a plan view.

In an embodiment, the bending area includes a bending start line at which the display panel starts to bend, and the protruding surface of the protruding portion or the concave surface of the groove is spaced apart from the bending start line in a plan view.

In an embodiment, the structural layer overlaps with the display area but not with the non-display area.

In an embodiment, the resin layer does not overlap with the bending area and overlaps with the display area and the non-display area.

In an embodiment, the protruding portion protrudes from the non-display area toward the bending area in a plan view.

In an embodiment, the protruding portion includes the protruding surface and curved surfaces extended from opposite sides of the protruding surface, and the protruding surface is formed as a straight line and the curved surfaces are formed in a rounded shape.

In an embodiment, the protruding surface and the bending start line are arranged parallel to each other, and a distance between the protruding surface and the bending start line is smaller than a distance between the protruding surface and the display area.

In an embodiment, the protruding portion includes a tip protruding from the protruding surface toward the bending area, and the tip overlaps with the non-display area but not with the bending area.

In an embodiment, the groove is concave from the non-display area toward the display area in a plan view.

In an embodiment, the groove includes the concave surface and curved surfaces extended from opposite sides of the concave surface, and the concave surface is formed as a straight line and the curved surfaces are formed in a rounded shape.

In an embodiment, the concave surface and the bending start line are arranged parallel to each other, and a distance between the concave surface and the bending start line is greater than a distance between the concave surface and the display area.

In an embodiment, the groove includes a tip protruding from the concave surface toward the bending area, and the tip overlaps with the non-display area but not with the bending area.

In an embodiment, the curved surfaces include a first curved surface extended from one side of the concave surface and a second curved surface extended from an opposite side of the concave surface, and a length of the first curved surface is different from a length of the second curved surface.

According to an embodiment of the present disclosure, a method for fabricating a display device, the method includes preparing a display panel member including a display area, a non-display area and a bending area, preparing a support film includes a support layer including a structural layer and a resin layer surrounding the structural layer, a first release film located on the support layer, a second release film located under the support layer a first coupling member located between the support layer and the first release film, and a second coupling member located between the support layer and the second release film, where the support film includes a concave groove on at least one side in a plan view, removing the first release film from the support film, coupling the support film to a rear surface of the display panel member, and cutting the display panel member and the support film to form a display panel and a support layer, where the groove of the support film is formed as a protruding portion or a groove of the support layer by cutting the display panel member and the support film, and a protruding surface of the protruding portion or a concave surface of the groove is spaced apart from the bending area toward the display area in a plan view.

In an embodiment, the coupling the support film to the rear surface of the display panel member include coupling the support film to the rear surface of the display panel member so that the structural layer overlaps with the display area but not with the non-display area.

In an embodiment, the cutting the display panel member and the support film includes cutting the display panel member and the support film using laser.

In an embodiment, the coupling the support film to the rear surface of the display panel member includes coupling the support film to the rear surface of the display panel member so that the groove of the support film overlaps with the non-display area and the bending area of the display panel member.

According to an embodiment of the present disclosure, an electronic device includes a display device for providing images, and a processor for transmitting an image data signal to the display device, where the display device includes, a display panel including a display area, a non-display area, and a bending area, a support layer located under the display panel, and a first coupling member located between the display panel and the support layer, the support layer includes a structural layer, a resin layer surrounding the structural layer, and a protruding portion or a groove located on one side of the resin layer, and a protruding surface of the protruding portion or a concave surface of the groove is spaced apart from the bending area toward the display area in a plan view.

According to an embodiment of the present disclosure, a support film of a display device includes a groove on one side in a plan view, so that it is possible to prevent bending defects as the support film does not intrude a bending area of a display panel during the fabrication process, and to prevent exposure of a non-display area of the display panel.

According to an embodiment of the present disclosure, a protruding surface of a protruding portion or a concave surface of a groove at a support layer is spaced apart from a bending area of a display device, so that it is possible to prevent bending defects of the display panel, and to prevent exposure of the non-display area of the display panel.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device which is unfolded according to an embodiment of the present disclosure.

FIG. 2 is a perspective view of the display device which is folded according to an embodiment of the present disclosure.

FIG. 3 is a perspective view showing a display device which is unfolded according to an embodiment of the present disclosure.

FIG. 4 is a perspective view of the display device which is folded according to an embodiment of the present disclosure.

FIG. 5 is a cross-sectional view of the display device which is unfolded according to an embodiment.

FIG. 6 is a perspective view showing a display panel according to an embodiment of the present disclosure.

FIG. 7 is a cross-sectional view showing the display panel according to an embodiment of the present disclosure.

FIG. 8 is an enlarged cross-sectional view showing a display panel according to an embodiment of the present disclosure.

FIG. 9 is a plan view showing a support film according to an embodiment of the present disclosure.

FIG. 10 is a cross-sectional view of the support film, taken along line X1-X1′ of FIG. 9.

FIG. 11 is a plan view showing a display panel and a support layer of a display device according to an embodiment of the present disclosure.

FIG. 12 is an enlarged view of area A shown in FIG. 11.

FIG. 13 is a view showing the protruding portion of the support layer according to the embodiment.

FIG. 14 is a cross-sectional view showing a display device according to an embodiment of the present disclosure.

FIG. 15 is a plan view showing a support layer of a display panel of a display device according to an embodiment of the present disclosure.

FIG. 16 is an enlarged view of area B of FIG. 15.

FIG. 17 is a view showing a groove of the support layer according to an embodiment.

FIG. 18 is a plan view showing a display panel and a support layer of a display device according to an embodiment of the present disclosure.

FIG. 19 is an enlarged view of area C of FIG. 18.

FIG. 20 is a view showing a protruding portion of the support layer according to an embodiment.

FIG. 21 is a plan view showing a display panel and a support layer of a display device according to an embodiment of the present disclosure.

FIG. 22 is an enlarged view of area D of FIG. 21.

FIG. 23 is a view showing a groove of the support layer according to an embodiment.

FIG. 24 is a flowchart for illustrating a method for fabricating (or providing) a display device according to an embodiment of the present disclosure.

FIGS. 25 to 34 are views showing processing steps of a method for fabricating a display device according to an embodiment of the present disclosure.

FIGS. 35 and 36 are views showing processing steps of a method for fabricating (or providing) a display device according to an embodiment of the present disclosure.

FIG. 37 is a block diagram of an electronic device according to an embodiment of the present disclosure.

FIG. 38 is a view showing electronic devices according to a variety of embodiments of the present disclosure.

### DETAILED DESCRIPTION

Advantages and features of the present disclosure and methods for achieving them will become apparent from embodiments described in detail below with reference to the accompanying drawings. However, the present disclosure is not limited to the embodiments disclosed herein and may be embodied in various different forms. These embodiments are provided to fully disclose the scope of the present disclosure and to fully convey the scope of the invention to those skilled in the art, and the invention is only defined by the scope of the claims.

When an element or a layer is referred to as being related to another element such as being “on” another element or layer, it includes not only being directly on the other element or layer but also being positioned thereon with one or more intervening layers or elements. In contrast, when an element or a layer is referred to as being related to another element such as being “directly on” another element or layer, no intervening layer is present therebetween.

Throughout this specification, like reference numerals refer to like components. Shapes, sizes, ratios, angles, quantities, and the like illustrated in the drawings for describing the embodiments are merely embodiments and the present disclosure is not limited to the illustrated matters.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

The features of various embodiments of the present disclosure may be partially or entirely combined or integrated with one another, and technical varieties of interoperations and operations may be possible. These embodiments may be implemented independently of one another or in combination with one another in a related manner.

Hereinafter, embodiments of the present disclosure will be described in detail with reference to the accompanying drawings.

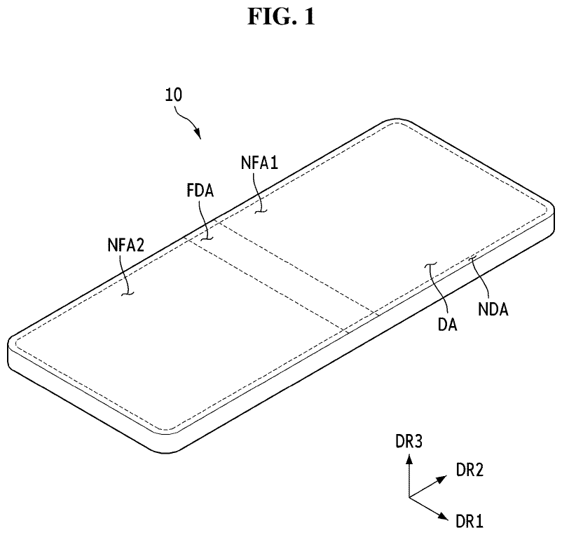

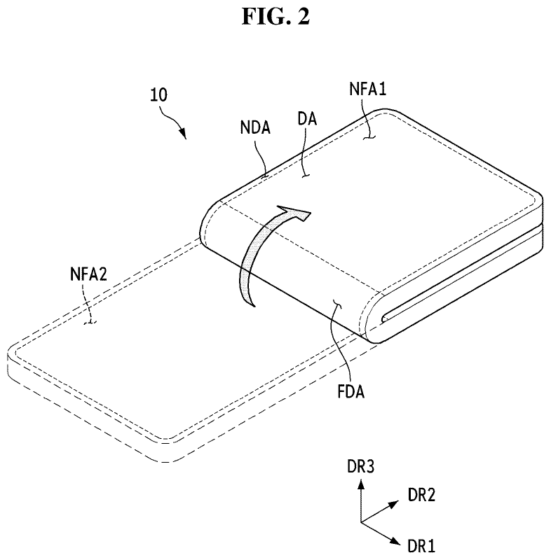

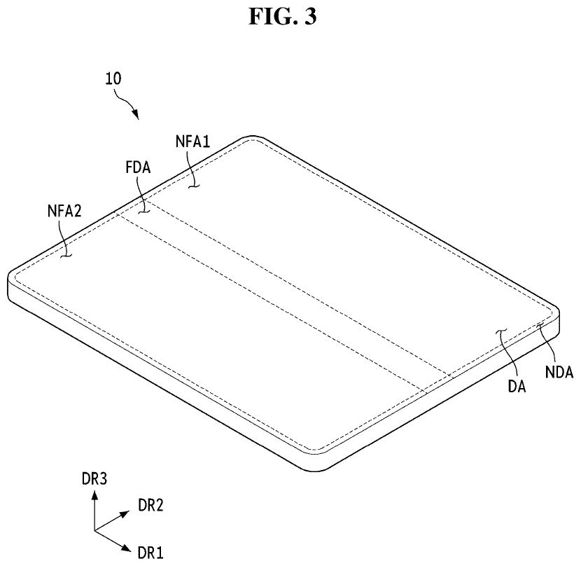

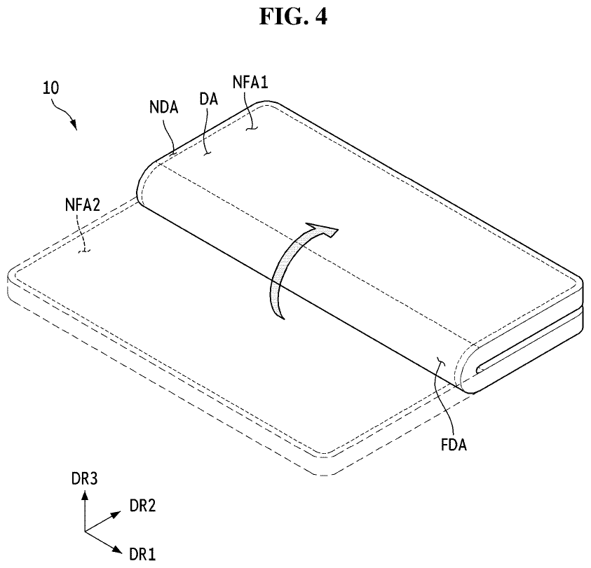

FIG. 1 is a perspective view of a display device 10 according to an embodiment of the present disclosure, when it is unfolded. FIG. 2 is a perspective view of the display device 10 according to the embodiment of the present disclosure, when it is folded. FIG. 3 is a perspective view showing a display device 10 according to an embodiment of the present disclosure, when it is unfolded. FIG. 4 is a perspective view of the display device 10 according to an embodiment of the present disclosure, when it is folded.

Referring to FIG. 1, a display device 10 according to an embodiment of the present disclosure may be a foldable display device. In the examples shown in the drawings, the display device 10 is employed by a smartphone, but the present disclosure is not limited thereto. For example, the display device 10 according embodiments of the present disclosure may be applied to a mobile phone, a tablet personal computer (PC), a personal digital assistant (PDA), a portable multimedia player (PMP), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, various medical apparatuses, various home appliances such as a refrigerator and a laundry machine, Internet of things (IoT) devices, etc., in addition to a smart phone. Hereinafter, embodiments of the present disclosure will be described with reference to the accompanying drawings.

As shown in FIGS. 1 and 2, a first direction DR1 may refer to a direction parallel to a side of the display device 10, for example, the horizontal direction of the display device 10 in a plan view. A second direction DR2 may refer to a direction parallel to another side of the display device 10 which meets the side of the display device 10, for example, the vertical direction of the display device 10 in a plan view. A third direction DR3 may refer to the thickness direction of the display device 10. A plane may be defined by two directions crossing each other among the various directions described above.

According to an embodiment of the present disclosure, the display device 10 may have a rectangular shape in a plan view. The display device 10 may have a rectangular shape with sharp corners or a rectangular shape with rounded corners in a plan view. The display device 10 may include two shorter sides extended in the first direction DR1 and two longer sides extended in the second direction DR2 in a plan view.

The display device 10 includes a display area DA and a non-display area NDA. The shape (e.g., the planar shape) of the display area DA may conform to the shape of the display device 10 in a plan view. For example, when the display device 10 is rectangular in a plan view, the display area DA may also be rectangular.

The display area DA may include a plurality of pixels to display images. The plurality of pixels may be arranged in a matrix pattern. The plurality of pixels may be, but is not limited to, a rectangle, a diamond, or a square in a plan view. For example, the plurality of pixels may be a quadrangle other than a rectangle, a diamond or a rectangle, a polygon other than a quadrangle, a circle, or an ellipse in a plan view.

The non-display area NDA may not include pixels and thus may not display images. The non-display area NDA may be located adjacent to the display area DA, such as being extended or disposed around the display area DA. The non-display area NDA may be disposed to surround the display area DA as shown in FIGS. 1 and 2, but the present disclosure is not limited thereto. The display area DA may be partially surrounded by the non-display area NDA.

According to an embodiment of the present disclosure, the display device 10 may remain folded as well as unfolded. The display device 10 may be folded inward (in-folding manner) so that the display device DA is located inside, as shown in FIG. 2. When the display device 10 is folded inward (in-folding), a part of the upper surface of the display device 10 may face another part thereof while portions of a lower surface face away from each other. For another example, the display device 10 may be folded outward (out-folding manner) such that the display surface is located outside. When the display device 10 is folded outward, a part of the lower surface of the display device 10 may face another part thereof while portions of the upper surface face away from each other. Portions facing away from each other may be exposed to outside the display device 10, so as to be visible from outside of the display device 10.

According to the embodiment of the present disclosure, the display device 10 may be a foldable device. As used herein, a foldable device refers to a display device 10 which can be folded and can be switched between a folded state and an unfolded state. When a device is folded, the device is typically folded at an angle of approximately 180°. It is, however, to be understood that the present disclosure is not limited thereto. For example, when a device is folded at an angle greater than or less than about 180°, e.g., at an angle of about 90° or more but less than about 180° or an angle of about 120° or more and less than about 180°, the device is also referred to as being folded. In addition, even when a device is not completely folded, the device may be referred to as being folded if the device is not unfolded but is somewhat bent. For example, even if a device is bent at an angle of about 90 degrees or less, the device may be referred to as being folded in order to distinguish it from being unfolded as long as the maximum folding angle is about 90 degrees or more. When the display device 10 is folded, the radius of curvature may be about 5 millimeters (mm) or less, such as in the range of approximately 1 mm to approximately 2 mm, or approximately 1.5 mm. It should be understood that the present disclosure is not limited thereto.

According to an embodiment of the present disclosure, the display device 10 may include a folding area FDA, and a non-folding area which is adjacent to the folding area FDA such as a first non-folding area NFA1 and a second non-folding area NFA2. The display device 10 can be folded at the folding area FDA, while it may remain unfolded or cannot be folded at the first non-folding area NFA1 and the second non-folding area NFA2.

The first non-folding area NFA1 may be disposed on one side, for example, the upper side of the folding area FDA. The second non-folding area NFA2 may be disposed on the other side, for example, the lower side of the folding area FDA. The folding area FDA of a folded device may be a curved area of the folded device with a predetermined curvature.

According to an embodiment of the present disclosure, the position of the folding area FDA in the display device 10 may be determined. In the display device 10, one or more folding areas FDA may be located at the determined position(s). According to an embodiment, the position of the folding area FDA may not be determined in the display device 10 but may be freely determined in different areas.

According to an embodiment of the present disclosure, the display device 10 may be folded in the second direction DR2, such as along a folding axis extended in the first direction DR1. Accordingly, the length of the display device 10 in the second direction DR2 may be reduced to about half, so that the display device 10 is easy to carry.

According to an embodiment of the present disclosure, the folding direction of the display device 10 is not limited to the second direction DR2. For example, the display device 10 may be folded in the first direction DR1, such as along a folding axis extended in the second direction DR2, and in this instance the length of the display device 10 in the first direction DR1 may be reduced to about half.

In FIGS. 1 and 2, each of the display area DA and the non-display area NDA overlaps the folding area FDA, the first non-folding area NFA1 and the second non-folding area NFA2. It is, however, to be understood that the present disclosure is not limited thereto. For example, each of the display area DA and the non-display area NDA may overlap at least one of the folding area FDA, the first non-folding area NFA1, and the second non-folding area NFA2. As being overlapping, elements may be disposed along a same line in a direction, such as along a thickness direction, a lateral direction, etc. For example, one element may be above or below another element along a thickness direction, so as to be be considered overlapping each other, without being limited thereto.

Referring to FIGS. 3 and 4, in the display device 10 according to the an embodiment, the first direction DR1 may be a direction parallel to one side of the display device 10 in a plan view, e.g., the vertical direction of the display device 10. The second direction DR2 may refer to a direction parallel to another side of the display device 10 which meets the side of the display device 10, e.g., the horizontal direction of the display device 10 in a plan view. The third direction DR3 may refer to the thickness direction of the display device 10. The display device 10 may include two longer sides extended in the first direction DR1 and two shorter sides extended in the second direction DR2 in a plan view.

According to this embodiment, the display device 10 may be folded inward (in-folding manner) such that the display area DA is positioned on the inside as shown in FIG. 4, or may be folded outward (out-folding manner) such that the display area DA is positioned on the outside. The display device 10 may include a folding area FDA, a first non-folding area NFA1, and a second non-folding area NFA2. The folding area FDA may be a curved area with a predetermined curvature. The display device 10 may be folded in the second direction DR2. Accordingly, the length of the display device 10 in the second direction DR2 may be reduced to about half, so that the display device 10 is easy to carry.

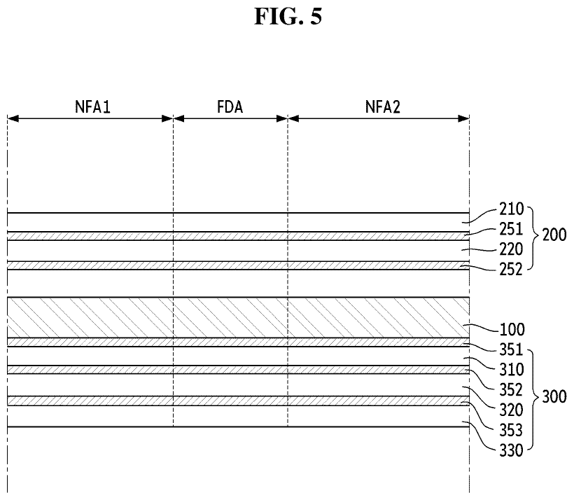

FIG. 5 is a cross-sectional view of the display device 10 according to the embodiment when it is unfolded.

Referring to FIG. 5, the display device 10 may include a display panel 100, a front stack structure 200 placed in front of the display panel 100, and a rear stack structure 300 placed at the back of the display panel 100. Each of the stack structures 200 and 300 may include one or more coupling members 251, 252, 351, 352 and 353. As used herein, the front side of the display panel 100 refers to the side where the display panel 100 displays images (e.g., a display side, a display screen, etc.), while the rear side thereof refers to the side opposite to the front side. A first surface of the display panel 100 is located on the front side, while a second surface of the display panel 100 is located on the rear side.

The display panel 100 displays images and may include a self-luminous display panel such as an organic light-emitting display panel (OLED), an inorganic light-emitting display panel (inorganic EL), a quantum-dot light-emitting display panel (QED), a micro LED display panel (micro-LED), a nano LED display panel (nano-LED), a plasma display panel (PDP), a field emission display panel (FED) and a cathode ray display panel (CRT), as well as a light-receiving display panel such as a liquid-crystal display panel (LCD) and an electrophoretic display panel (EPD) In the following description, the organic light-emitting display panel will be described as an example of the display panel 100, and the organic light-emitting display panel will be simply referred to as the display panel 100 unless specifically stated otherwise. It is, however, to be understood that the embodiments of the present disclosure are not limited to the organic light-emitting display panel, and any other display panel listed above or well known in the art may be employed without departing from the scope of the present disclosure.

The display panel 100 may further include a touch member. The touch member may be implemented as a panel or film separated from the display panel 100 to be attached on the display panel 100 (not shown) or may be implemented in the form of a touch layer inside the display panel 100. Although the touch member is provided inside the display panel 100 to be included in the display panel 100 in the following description, it is to be understood that the present disclosure is not limited thereto.

The front stack structure 200 may be placed in front of the display panel 100. The front stack structure 200 may include a shock-absorbing layer 220 and a cover window 210 sequentially stacked from the display panel 100 to the front side.

The shock-absorbing layer 220 can protect structures such as the display panel 100 thereunder from external impact. According to the embodiment, the shock-absorbing layer 220 may be a polymer film. The polymer film may include, for example, at least one selected from polyethylene terephthalate (PET), polyethylene naphthalate (PEN), polyether sulfone (PES), polyimide (PI), polyarylate (PAR), polycarbonate (PC), polymethyl methacrylate (PMMA) and cyclo olefin copolymer (COC) resin.

The cover window 210 may be placed in front of the shock-absorbing layer 220. The cover window 210 serves to protect the display panel 100. The cover window 210 may be made of (or include) a transparent material. The cover window 210 may include, for example, glass or plastic.

When the cover window 210 includes glass, the glass may be ultra-thin glass (UTG) or thin glass. When the glass is formed as ultra-thin glass or thin glass, it may have flexibility and may be curved, bent, folded or rolled. The thickness of the glass may be, for example, in the range of about 10 micrometers (μm) to about 300 μm, such as about 10 μm to about 100 μm, or approximately 30 μm.

The glass of the cover window 210 may include soda lime glass, alkali alumino silicate glass, borosilicate glass, or lithium alumina silicate glass. The glass of the cover window 210 may include chemically or thermally tempered glass to have a high strength. The chemical tempering may be carried out via an ion exchange process in an alkali salt. The ion exchange process may be performed two or more times. In addition, the cover window 210 may be a polymer film having thin glasses coated on its opposite surfaces.

When the cover window 210 includes a plastic, it may be more advantageous to exhibit flexible characteristics such as folding. Examples of plastics applicable to the cover window 210 may include, but are not limited to, polyimide, polyacrylate, polymethylmethacrylate (PMMA), polycarbonate (PC), polyethylenenaphthalate (PEN), polyvinylidene chloride, polyvinylidene difluoride (PVDF), polystyrene, ethylene vinylalcohol copolymer, polyethersulphone (PES), polyetherimide (PEI), polyphenylene sulfide (PPS), polyallylate, tri-acetyl cellulose (TAC), cellulose acetate propionate (CAP) and the like. The plastic cover window 210 may include one or more of the plastic materials listed above.

The cover window 210 may include a protective layer at the top. The protective layer may have a hardness sufficient to protect the cover window 210 and a modulus (such as an elastic modulus) sufficient to prevent deformation when the display device 10 is repeatedly folded and unfolded. In addition, the protective layer may include layers having functions such as an anti-glare layer, an anti-fingerprint layer, and an anti-reflection layer. The protective layer may be implemented as a panel or film further on top of the cover window 210 shown so as to be attached on the cover window 210 or may be implemented in the form of a layer inside the cover window 210 shown.

The rear stack structure 300 may be placed at the back of the display panel 100. The rear stack structure 300 may include a support layer 310, a cushion layer 320 and a plate 330 sequentially stacked from the display panel 100 to the rear side.

The support layer 310 may be positioned at the back of the display panel 100. The support layer 310 may support the display panel 100 which is flexible and improve foldability. The support layer 310 will be described in more detail.

The cushion layer 320 may be placed at the back of the support layer 310. The cushion layer 320 may absorb an external shock to prevent the display panel 100 from being damaged. The cushion layer 320 may be made up of a single layer or multiple layers stacked on one another. The cushion layer 320 may include a material having elasticity such as polyurethane and a polyethylene resin, for example. According to the embodiment of the present disclosure, the cushion layer 320 may be made of a foam material similar to a sponge.

The plate 330 may be placed at the back of the cushion layer 320. The plate 330 may be a support structure for coupling the display device 10 with a case (not shown) of the display device 10. The plate 330 may include a material having rigidity. According to an embodiment of the present disclosure, the plate 330 may be made of a single metal or a metal alloy such as stainless steel (SUS).

A heat dissipation member may be further placed at the back of the plate 330 in order to efficiently dissipate heat from the display panel 100. The heat dissipation member may include a first heat dissipation layer including graphite or carbon nanotubes, and a second heat dissipation layer formed of a thin metal film such as copper, nickel, ferrite and silver, which can block electromagnetic waves and have high thermal conductivity. The heat dissipation member may be implemented as a panel or film further on the plate 330 shown so as to be attached on the plate 330 or may be implemented in the form of a layer inside the plate 330.

The rear stack structure 300 may include rear coupling members 351 to 353 which couple adjacent ones of the elements stacked on one another. For example, the first coupling member 351 may be placed between the display panel 100 and the support layer 310 to couple them together, the second coupling member 352 may be placed between the support layer 310 and the cushion layer 320 to couple them together, and the third coupling member 353 may be placed between the cushion layer 320 and the plate 330 to couple them together.

The front stack structure 200 may include front coupling members 251 and 252 each coupling between adjacent ones of the elements stacked on one another. For example, a fourth coupling member 251 may be placed between the cover window 210 and the shock-absorbing layer 220 to couple them together, and a fifth coupling member 252 may be placed between the shock-absorbing layer 220 and the display panel 100 to couple them together. The front coupling members 251 and 252 may attach the layers to a surface of the display panel 100, and may be optically transparent.

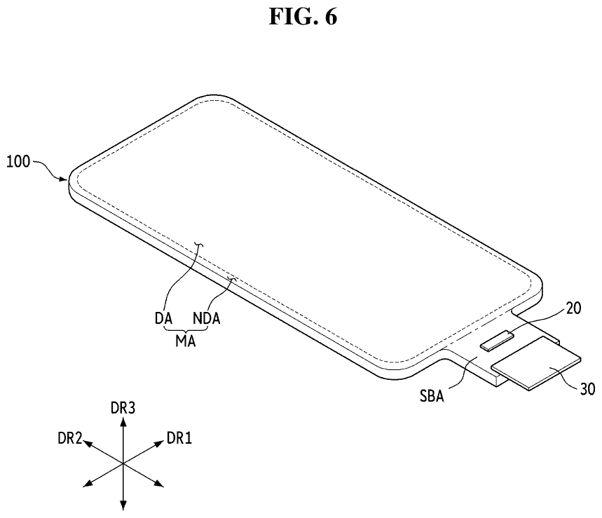

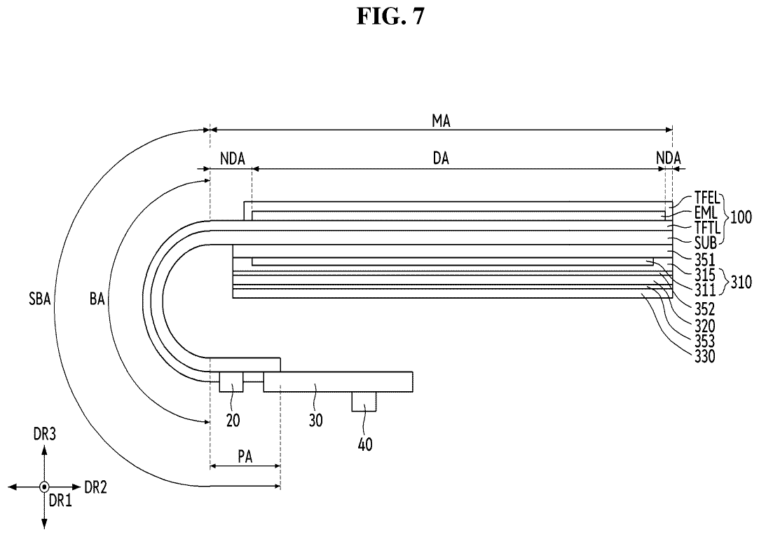

FIG. 6 is a perspective view showing a display panel 100 according to an embodiment of the present disclosure. FIG. 7 is a cross-sectional view showing the display panel 100 according to the embodiment of the present disclosure. FIG. 7 shows the display panel 100 and the support layer 310 together.

Referring to FIG. 6, the display panel 100 according to the embodiment may include a display driver circuit 20 and a circuit board 30.

The display panel 100 may be formed (or provided) in a rectangular plane having shorter sides in the first direction DR1 and longer sides in the second direction DR2 which intersects the first direction DR1. In addition, the display panel 100 may have a thickness in the third direction DR3 which intersects the first direction DR1 and the second direction DR2. Each of the corners where the shorter side in the first direction DR1 meets the longer side in the second direction DR2 may be rounded with a curvature or may be a right angle. The shape of the display panel 100 in a plan view is not limited to a quadrangular shape, but may be formed in a different polygonal shape, a circular shape, or an elliptical shape. The display panel 100 may be formed flat, but the present disclosure is not limited thereto. For example, the display panel 100 may be formed at left and right ends, and may include a curved portion having a constant curvature or a varying curvature. In addition, the display panel 100 may be flexible so that it can be curved, bent, folded or rolled.

The display panel 100 may include the main area MA and a subsidiary area SBA. The main area MA and the subsidiary area SBA may together provide a total planar area of the display panel 100, such as when it is unfolded.

The main area MA may include a display area DA where images are displayed, and a non-display area NDA around the display area DA. The display area DA may occupy most of the main area MA. The display area DA may be located at the center of the main area MA, that is, spaced apart from outer edges of the main area MA. The non-display area NDA may be disposed adjacent to the display area DA in a planar direction, such as along a DR1-DR2 plane. The non-display area NDA may be located on the outer side of the display area DA. The non-display area NDA may surround the display area DA. The non-display area NDA may be defined as the edge area of the display panel 100. In the display area DA, a plurality of pixels may be arranged to display images. The display area DA may include the pixels for displaying images. For example, the display area DA may include pixel areas where the pixels are arranged.

The subsidiary area SBA may be extended from one side of the main area MA, in the second direction DR2. The length of the subsidiary area SBA in the second direction DR2 may be smaller than the length of the main area MA in the second direction DR2. The length of the subsidiary area SBA in the first direction DR1 may be smaller than the length of the main area MA in the first direction DR1. The subsidiary area SBA may be bent and a portion thereof may be located under the display panel 100. In this instance, the display panel 100 which is bent at the subsidiary area SBA may include the subsidiary area SBA overlapping with the main area MA in the third direction DR3.

The display panel 100 may further include a bending area BA and a pad area PA.

The bending area BA may be extended from one side of the main area MA in the second direction DR2. The length of the bending area BA in the second direction DR2 may be smaller than the length of the subsidiary area SBA in the second direction DR2. The length of the bending area BA in the first direction DR1 may be smaller than the length of the main area MA in the first direction DR1. The bending area BA may be bent and a portion thereof may be located on a side of the display panel 100 and under it. The main area MA and the pad area PA may be spaced apart from each other with the bending area BA between the areas, such as along a planar direction of the display panel 100.

The pad area PA may be extended from one side of the bending area BA, in the second direction DR2. The pad area PA may be the other area (e.g., a remaining area) of the subsidiary area SBA, other than the bending area BA. The length of the pad area PA in the second direction DR2 may be smaller than the length of the subsidiary area SBA in the second direction DR2. In a display panel 100 which is bent at the bending area BA (or at the subsidiary area SBA), the pad area PA may be located under the display panel 100, in which case the pad area PA may overlap with the main area MA in the third direction DR3.

The display driver circuit 20 may generate signals and voltages for driving the display panel 100. The display driver circuit 20 may be implemented as an integrated circuit (IC) and may be attached to the display panel 100 at the subsidiary area SBA of the display panel 100, by a chip on glass (COG) technique, a chip on plastic (COP) technique, or an ultrasonic bonding. Alternatively, the display driver circuit 20 may be attached on the circuit board 30 by the chip-on-film (COF) technique.

The circuit board 30 may be attached to one end of the subsidiary area SBA of the display panel 100. Accordingly, the circuit board 30 as a component external to the display panel 100, may be electrically connected to the display panel 100 and the display driver circuit 20. The display panel 100 and the display driver circuit 20 may receive digital video data, timing signals, and driving voltages through the circuit board 30. The circuit board 30 may be a flexible printed circuit board, a printed circuit board, or a flexible film such as a chip on film.

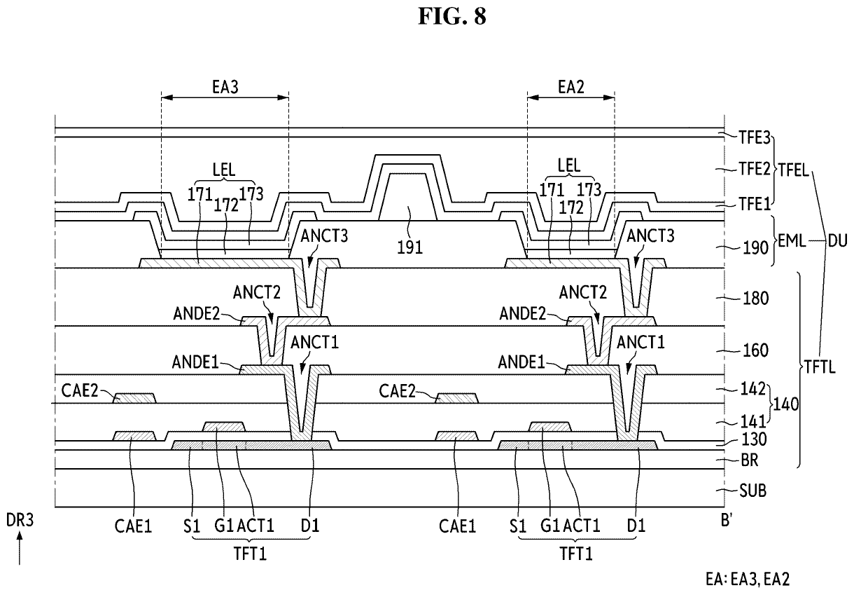

FIG. 8 is a cross-sectional view showing a display panel 100 according to an embodiment of the present disclosure.

Referring to FIG. 8, the display panel 100 may include the substrate SUB, the thin-film transistor layer TFTL, the emission material layer EML, and the encapsulation layer TFEL.

The substrate SUB may be made of an insulating material such as a polymer resin. For example, the substrate SUB may be made of polyimide. The substrate SUB may be a flexible substrate which can be bent, folded, or rolled.

A barrier layer BR may be located on the substrate SUB. The barrier layer BR is a film for protecting the thin-film transistors of the thin-film transistor layer TFTL and an emissive layer 172 of the emission material layer EML. The barrier layer BR may be made up of multiple inorganic films stacked on one another alternately. For example, the barrier layer BR may be made up of multiple layers in which one or more inorganic layers of a silicon nitride layer, a silicon oxynitride layer, a silicon oxide layer, a titanium oxide layer and an aluminum oxide layer are alternately stacked on one another.

A first thin-film transistor TFT1 may be located on the barrier layer BR. The first thin-film transistor TFT1 may include a first active layer ACT1 and a first gate electrode G1.

A first active layer ACT1 of the first thin-film transistor TFT1 may be located on the barrier layer BR. The first active layer ACT1 of the first thin-film transistor TFT1 may include polycrystalline silicon, monocrystalline silicon, low-temperature polycrystalline silicon, amorphous silicon, or oxide semiconductor. The first active layer ACT1 may include a channel.

The first active layer ACT1 may include a first source region S1 and a first drain region D1 disposed with the channel therebetween. The channel may be an area which overlaps the first gate electrode G1 in the third direction DR3, which is the thickness direction of the substrate SUB. The first source region S1 may be disposed on one side of the first active layer ACT1, and the first drain region D1 may be disposed on the opposite side of the first active layer ACT1. The first source region S1 and the first drain region D1 may not overlap with the first gate electrode G1 in the third direction DR3. The first source region S1 and the first drain region D1 may have conductivity (e.g., electrical conductivity) by doping a silicon semiconductor or an oxide semiconductor with ions or impurities.

A first gate insulator 130 may be placed (or provided) on the first active layer ACT1 of the first thin-film transistor TFT1. The first gate insulator 130 may be formed of an inorganic layer, for example, a silicon nitride layer, a silicon oxynitride layer, a silicon oxide layer, a titanium oxide layer, or an aluminum oxide layer.

The first gate electrode G1 of the first thin-film transistor TFT1 and a first capacitor electrode CAE1 may be arranged on the gate insulator 130. The first gate electrode G1 may overlap the first active layer ACT1 in the third direction DR3. Although the first gate electrode G1 and the first capacitor electrode CAE1 are spaced apart from each other in the example shown in FIG. 4, the first gate electrode G1 and the first capacitor electrode CAE1 may be connected (e.g., physically, within a single pattern, electrically, etc.) with each other. The first gate electrode G1 and the capacitor electrode CAE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof. The first gate electrode G1 and the capacitor electrode CAE1 may be in a same layer as each other. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

A first interlayer dielectric layer 141 may be placed on the first gate electrode G1 of the first thin-film transistor TFT1 and the first capacitor electrode CAE1. The first interlayer dielectric layer 141 may be formed of an inorganic layer, for example, a silicon nitride layer, a silicon oxynitride layer, a silicon oxide layer, a titanium oxide layer, or an aluminum oxide layer. The first interlayer dielectric layer 141 may be made up of a plurality of inorganic films.

The second capacitor electrode CAE2 may be placed on the first interlayer dielectric layer 141. The second capacitor electrode CAE2 may overlap the first capacitor electrode CAE1 of the first thin-film transistor TFT1 in the third direction DR3. When the first capacitor electrode CAE1 is connected to the first gate electrode G1, the second capacitor electrode CAE2 may overlap the first gate electrode G1 in the third direction DR3. Since the first interlayer dielectric layer 141 has a dielectric constant, a capacitor can be formed by the first capacitor electrode CAE1, the second capacitor electrode CAE2 and the first interlayer dielectric layer 141 arranged therebetween. The second capacitor electrode CAE2 may be made up of (or include) a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second interlayer dielectric layer 142 may be disposed over the second capacitor electrode CAE2. The second interlayer dielectric layer 142 may be formed of an inorganic layer, for example, a silicon nitride layer, a silicon oxynitride layer, a silicon oxide layer, a titanium oxide layer, or an aluminum oxide layer. The second interlayer dielectric layer 142 may be made up of a plurality of inorganic films.

A first anode connection electrode ANDE1 may be disposed on the second interlayer dielectric layer 142. The first anode connection electrode ANDE1 may be connected to the first drain electrode D1 of the first thin-film transistor TFT1 through a first connection contact hole ANCT1 which penetrates the first gate insulator 130, the first interlayer dielectric layer 141 and the second interlayer dielectric layer 142. The first anode connection electrode ANDE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A first planarization layer 160 may be placed over the first anode connection electrode ANDE1 for providing a flat surface over level differences due to the first thin-film transistor TFT1. The first planarization layer 160 may be formed of an organic layer such as an acryl resin, an epoxy resin, a phenolic resin, a polyamide resin and a polyimide resin.

A second anode connection electrode ANDE2 may be located on the first planarization layer 160. The second anode connection electrode ANDE2 may be connected to the first anode connection electrode ANDE1 through a second connection contact hole ANCT2 penetrating the first planarization layer 160. The second anode connection electrode ANDE2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second planarization layer 180 may be located on the second anode connection electrode ANDE2. The second planarization layer 180 may be formed of an organic layer such as an acryl resin, an epoxy resin, a phenolic resin, a polyamide resin and a polyimide resin.

Light-emitting elements LEL and a bank 190 may be arranged on the second planarization layer 180. Each of the light-emitting elements LEL includes a pixel electrode 171, an emissive layer 172, and a common electrode 173.

The pixel electrode 171 may be disposed on the second planarization layer 180. The pixel electrode 171 may be connected to the second anode connection electrode ANDE2 through a third connection contact hole ANCT3 penetrating the second planarization layer 180.

In the top-emission structure in which light exits from the emissive layer 172 toward the common electrode 173, the pixel electrode 171 may be made of a metal material having a high reflectivity such as a stack structure of aluminum and titanium (Ti/Al/Ti), a stack structure of aluminum and indium tin oxide (ITO) (ITO/Al/ITO), an APC alloy and a stack structure of APC alloy and ITO (ITO/APC/ITO). The APC alloy is an alloy of silver (Ag), palladium (Pd) and copper (Cu).

The bank 190 may partition the pixel electrode 171 on the second planarization layer 180 to define the emission areas EA (e.g., light emitting areas). The emission areas EA may include a light emitting area provided in plural such as an emission area EA2 and an emission area EA3. A solid portion (e.g., solid material) of the bank 190 may be located to cover the edges of the pixel electrode 171. The bank 190 may define an opening therein at which the pixel electrode 171 is exposed. The opening may correspond to an emission area among the emission areas EA. The bank 190 may include an organic film such as an acryl resin, an epoxy resin, a phenolic resin, a polyamide resin and a polyimide resin.

In the emission areas EA, the pixel electrode 171, the emissive layer 172 and the common electrode 173 are stacked on one another sequentially, so that holes from the pixel electrode 171 and electrons from the common electrode 173 are recombined in the emissive layer 172 to emit light.

The emissive layer 172 may be placed on the pixel electrode 171 and the bank 190. The emissive layer 172 may include an organic material to emit light of a particular color. For example, the emissive layer 172 may include a hole transporting layer, an organic material layer, and an electron transporting layer.

The common electrode 173 may be located on the emissive layer 172. The common electrode 173 may cover the emissive layer 172. The common electrode 173 may be a common layer formed across the emission areas EA. A capping layer may be formed on the common electrode 173.

In the top-emission organic light-emitting diode, the common electrode 173 may include a transparent conductive material (TCP) such as ITO and IZO which can transmit light, or a semi-transmissive conductive material such as magnesium (Mg), silver (Ag) and an alloy of magnesium (Mg) and silver (Ag). When the common electrode 173 is formed of a semi-transmissive conductive material, the light extraction efficiency can be increased by using microcavities.

A spacer 191 may be located on the bank 190. In an embodiment of providing the electronic device, the spacer 191 may support a mask during a process of fabricating the emissive layer 172. The spacer 191 may be implemented as an organic layer such as an acryl resin, an epoxy resin, a phenolic resin, a polyamide resin and a polyimide resin.

The encapsulation layer TFEL may be located on the common electrode 173. The encapsulation layer TFEL may include at least one inorganic film to prevent permeation of oxygen or moisture into the emissive layer 172 of the emission material layer EML. In addition, the encapsulation layer TFEL may include at least one organic film to protect the emission material layer EML from particles such as dust.

The encapsulation layer TFEL may include a first inorganic encapsulation film TFE1, an organic encapsulation film TFE2 and a second inorganic encapsulation film TFE3.

The first inorganic encapsulation film TFE1 and the second inorganic encapsulation film TFE3 may include at least one inorganic insulating material selected from aluminum oxide, titanium oxide, titanium oxide, hafnium oxide, zinc oxide, silicon oxide, silicon nitride, and silicon oxy nitride. The organic encapsulation film TFE2 may include monomers. The organic encapsulation film TFE2 may be formed by applying monomers and then curing them using heat or ultraviolet light.

Hereinafter, a support film 400 for forming the support layer 310 provided in the display device 10 will be described.

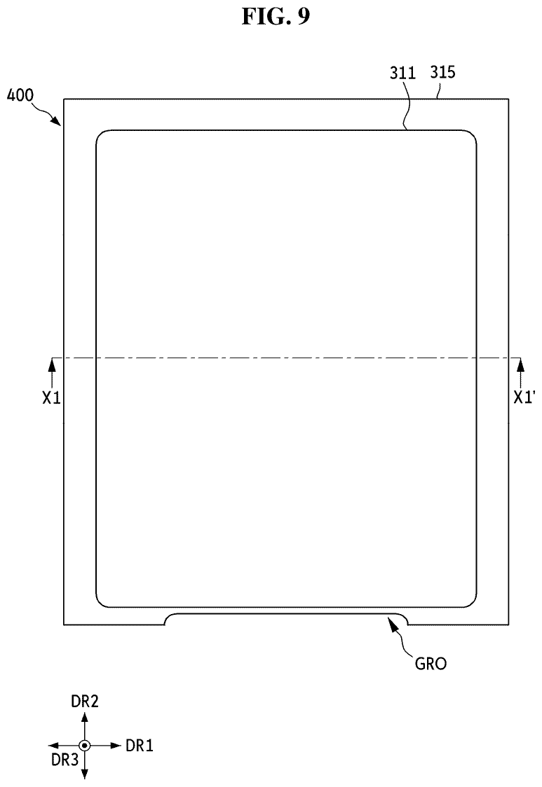

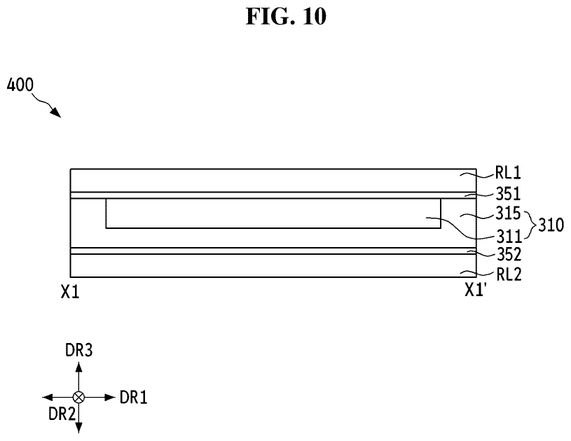

FIG. 9 is a plan view showing a support film 400 according to an embodiment of the present disclosure. FIG. 10 is a cross-sectional view of the support film, taken along line X1-X1′ of FIG. 9. The support film 400 shown in FIGS. 9 and 10 shows the structure prior to bonding the support layer 310 to the display panel 100. The support film 400 may be referred to as a preliminary support layer.

Referring to FIGS. 9 and 10, a support film 400 according to the embodiment may include a support layer 310 including a structural layer 311 and a resin layer 315, a first coupling member 351, a second coupling member 352, a first release film RL1, and a second release film RL2.

The support layer 310 may include the structural layer 311 and the resin layer 315. The structural layer 311 may be surrounded by the resin layer 315. The structural layer 311 may include glass or metal. When the structural layer 311 includes glass, the glass may include ultra-thin glass (UTG) or hybrid thin glass having a thickness of about 200 μm or less. As another example, when the structural layer 311 includes a metal, the metal may include aluminum (Al), titanium (Ti), copper (Cu), gold (Au), zinc (Zn), molybdenum (Mo), tungsten (W), nickel (Ni), chromium (Cr), magnesium (Mg), silver (Ag), or an alloy thereof. As another example, the structural layer 311 may include a metal compound. The metal compound may be a transparent conductive material (TCO) such as ITO and IZO, a metal oxide/nitride such as aluminum oxide (Al₂O₃), aluminum oxynitride (AlON), spinel (MgAl₂O₄), silicon oxide (SiO₂), silicon nitride (Si₃N₄), gallium nitride (GaN), and aluminum nitride (AlN), or a metal halide such as zinc sulfide (ZnS) and zinc selenide (ZnSe).

The thickness of the structural layer 311 may range from about 10 μm to about 500 μm, e.g., about 10 μm to about 200 μm. If the structural layer 311 is relatively thin with a thickness of about 200 μm or less, the stability can be maintained even when the display panel 100 is repeatedly folded and unfolded. The structural layer 311 has a relatively high hardness and can protect the display panel 100.

The resin layer 315 may surround the structural layer 311. For example, the resin layer 315 may surround the lower surface and side surfaces of the structural layer 311, and an upper surface of the structural layer 311 may be exposed to outside the resin layer 315. The resin layer 315 may protect the structural layer 311 and may assist the folding and unfolding operations of the structural layer 311. In an embodiment, the structural layer 311 may have a hardness, rigidity, etc. higher than that of the resin layer 315, without being limited thereto.

According to the embodiment of the present disclosure, the upper surface of the resin layer 315 and the upper surface of the structural layer 311 may be aligned with each other. For example, the upper surface of the resin layer 315 and the upper surface of the structural layer 311 may be on the same plane, e.g., coplanar with each other. The upper surface of the resin layer 315 and the upper surface of the structural layer 311 may be made flat to facilitate adhesion to the rear surface of the display panel 100.

In addition, the thickness of the resin layer 315 may be greater than the thickness of the structural layer 311. For example, the thickness of a portion of the resin layer 315 in the third direction DR3 which does not overlap with the structural layer 311 may be greater than the thickness of the structural layer 311. On the other hand, the thickness of a portion of the resin layer 315 in the third direction DR3 which overlaps with the structural layer 311 may be smaller than the thickness of the structural layer 311. It should be understood, however, that the embodiments of the present disclosure are not limited thereto. The thickness of the portion of the resin layer 315 in the third direction DR3 which overlaps with the structural layer 311 may be equal to or greater than the thickness of the structural layer 311.

The resin layer 315 may include a material selected from polyethylene terephthalate (PET), polyimide (PI), polytetrafluoroethylene (PTFE), polyether ether ketone (PEEK), polycarbonate (PC), polyphenylene sulfide (PPS), and combinations thereof. It is, however, to be understood that the types of these materials are not limited.

The first release film RL1 and the second release film RL2 may form the upper and lower surfaces of the support film 400, respectively. For example, the first release film RL1 may be placed on the upper surfaces of the resin layer 315 and the structural layer 311, and the second release film RL2 may be placed on the lower surface of the resin layer 315. The first release film RL1 and the second release film RL2 may be detached and removed when it is bonded to the display panel 100. As such, the release layers are detachable to and detachable from remaining layers of the support film 400

The first coupling member 351 may be placed between the first release film RL1 and the support layer 310, and the second coupling member 352 may be placed between the second release film RL2 and the support layer 310. The first coupling member 351 and the second coupling member 352 may include a transparent adhesive material such as a pressure sensitive adhesive film (PSA), an optically clear adhesive film (OCA), an optically clear adhesive resin (OCR), and a combination thereof.

According to the embodiment of the present disclosure, the support film 400 may include a groove GRO. The groove GRO may be located on one of the sides of the support film 400, such as being recessed from an outer side of the support film 400. For example, the groove GRO may be located on the lower side of the support film 400 in a plan view. The groove GRO may have a structure in which at least a part of a side of the support film 400 is concaved toward the structural layer 311. For example, the groove GRO may be concaved toward the structural layer 311 in a plan view, such as to be open to outside the support film 400.

According to the embodiment of the present disclosure, the sides of the stacked structure which define the groove GRO of the support film 400, may be rounded. As shown in FIG. 9, the sides of the groove GRO may be rounded and convex toward the structural layer 311. As another example, the sides of the groove GRO may be rounded and convex toward the lower side. Alternatively, the sides of the groove GRO of the support film 400 may meet at a right angle. It should be understood, however, that the embodiments of the present disclosure are not limited thereto. A variety of planar shapes of the sides of the stacked structure which define the groove GRO may be applied.

Among layers of the stacked structure which define the groove GRO, the groove GRO may be formed (or defined) in the resin layer 315, the first release film RL1, the second release film RL2, the first coupling member 351 and the second coupling member 352. Each of these layers may define a sub-groove and the sub-grooves may overlap each other to provide the groove GRO. The groove GRO may be spaced apart from the structural layer 311 in a plan view. In other words, the groove GRO is not formed in the structural layer 311 and a portion of the remaining layers described above may be defined between the outer side of the structural layer 311 and the groove GRO.

The groove GRO formed in the support film 400 may be provided so as not to interfere with the bending of the bending area BA of the display panel 100, as will be described later. If the support layer 310 of the support film 400 intrudes the bending area BA of the display panel 100, there may be a defect that the bending start point of the display panel 100 is changed by the support layer 310.

Accordingly, the support film 400 according to the embodiment includes the groove GRO and is spaced apart from the bending area BA of the display panel 100, so that the bending area BA of the display panel 100 can be bent normally.

In an embodiment, a support layer 310 is attachable to a display device 10 having a bending area BA extended from a display area DA and a first coupling member 351 is configured to attach the support layer 310 to the display device 10. Here, a side of the support film defines a protruding portion (like at SMS described below) or a concave portion (like at GMS described below). The support layer 310 which is attached to the display device 10 includes the side of the support film 400 closest to the bending area BA together with the protruding portion or the concave portion being spaced apart from the bending area BA.

FIGS. 9 and 10 shows the support film 400 before it is attached to the display panel 100. When attached to the rear surface of the display panel 100, the first and second release films RL1 and RL2 of the support film 400 are removed before the support film 400 is attached to the display panel 100, and a cutting process is carried out after the support film 400 has been attached to the display panel 100. The first coupling member 351, the second coupling member 352 and the support layer 310 which start unattached to the display panel 100 (e.g., within the support film 400), may remain in a final display device 10 after attachment of the first coupling member 351, the second coupling member 352 and the support layer 310 to the display panel 100. Accordingly, the groove GRO formed in the support film 400 may be formed differently in the form of a protruding portion PRP or a groove GRO provided in the support layer 310 in the display device 10.

Hereinafter, a display device 10 having a support layer 310 including a protruding portion PRP or a groove GRO (e.g., a concave portion) will be described. An end of the support layer 310 which is attached and overlapping the display panel 100, may include a concave portion and a protruding portion variously arranged along a length of the end. For the feature labeled 310, 311 and 315 in the views and hereinafter described, it will be understood that the first coupling member 351 and the second coupling member 352 may also be present at the area indicated by 310, 311 and 315, without being limited thereto.

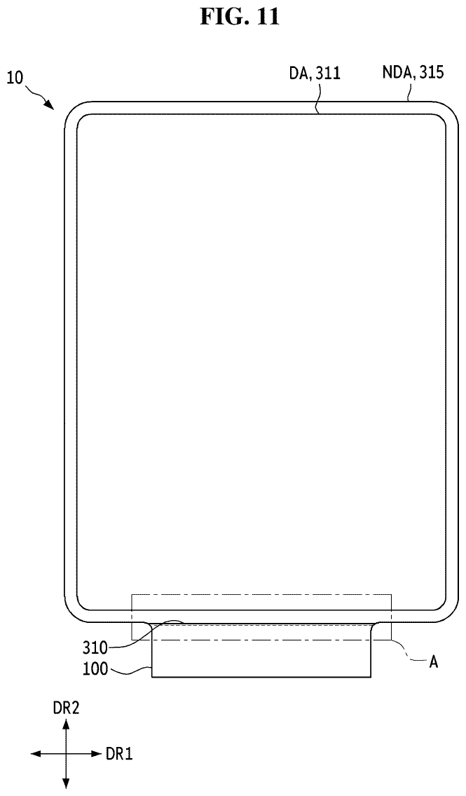

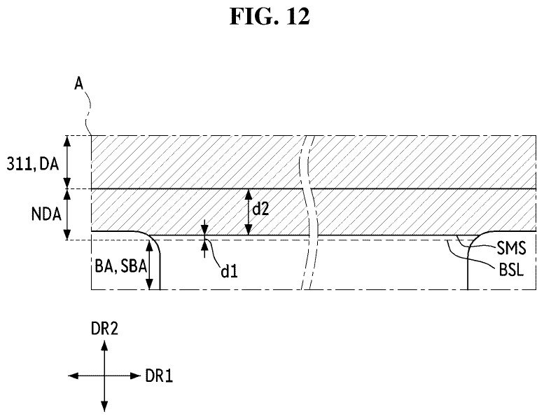

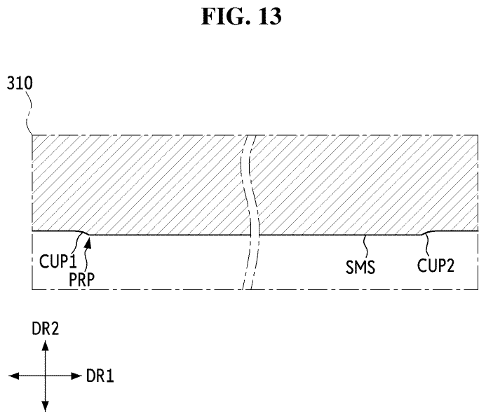

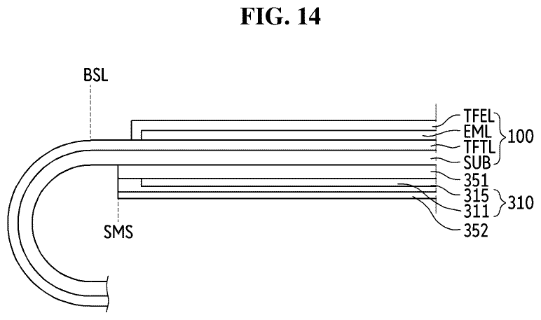

FIG. 11 is a plan view showing a display panel 100 and a support layer 310 of a display device 10 according to an embodiment of the present disclosure. FIG. 12 is an enlarged view of area A shown in FIG. 11. FIG. 13 is a view showing the protruding portion PRP of the support layer 310 according to the embodiment. FIG. 14 is a cross-sectional view showing a display device 10 according to an embodiment of the present disclosure. It should be noted that FIGS. 11 and 12 show the rear side of the display panel 100 coupled with the support layer 310.

Referring to FIGS. 11 to 14, the display device 10 according to the embodiment may include a display panel 100, and a support layer 310 coupled to the rear surface of the display panel 100.

The display panel 100 may include a display area DA, a non-display area NDA adjacent to or surrounding the display area DA, and a subsidiary area SBA protruding from the main area MA (e.g., protruding from the non-display area NDA or being part of the overall non-display area NDA).

The support layer 310 may be coupled with the display panel 100 such that it overlaps with the display area DA and the non-display area NDA. The structural layer 311 of the support layer 310 may overlap with the display area DA of the display panel 100. The structural layer 311 of the support layer 310 may be arranged in the display area DA of the display panel 100. For example, the size of the structural layer 311 of the support layer 310 may be equal to the size of the display area DA of the display panel 100, where sizes may be planar areas of respective features. The structural layer 311 of the support layer 310 may not overlap with the non-display area NDA of the display panel 100. It should be understood, however, that the embodiments of the present disclosure are not limited thereto. The size of the structural layer 311 of the support layer 310 may be greater than or less than the size of the display area DA of the display panel 100. The sides (e.g., outer sides) of the support layer 310 may be aligned with the sides of the display panel 100. For example, at least a part of the lower side, the upper side, the left side and the right side of the support layer 310 may be aligned with at least a part of the lower side, the upper side, the left side and the right side of the display panel 100, respectively.

The resin layer 315 of the support layer 310 may overlap with the display area DA and non-display area NDA of the display panel 100. The resin layer 315 may cover the entire display area DA of the display panel 100 and may cover at least a part of the non-display area NDA. For example, the resin layer 315 may cover the non-display area NDA, leaving an exposed part of the non-display area NDA which is adjacent to the subsidiary area SBA. In addition, the resin layer 315 may not overlap with the subsidiary area SBA or the bending area BA of the display panel 100. For example, the resin layer 315 may not overlap with the bending area BA of the subsidiary area SBA of the display panel 100. That is to say, the resin layer 315 may be spaced apart from the bending area BA of the display panel 100 in a plan view.

According to the embodiment of the present disclosure, the support layer 310 may include a protruding portion PRP. The protruding portion PRP may protrude from one side of the support layer 310. The protruding portion PRP may protrude toward the bending area BA or the subsidiary area SBA in the non-display area NDA of the display panel 100. The protruding portion PRP may be located in the non-display area NDA of the display panel 100 and is not extended beyond the bending area BA or the subsidiary area SBA. For example, the protruding portion PRP may overlap with the non-display area NDA of the display panel 100 but not with the bending area BA or the subsidiary area SBA. According to an embodiment of the present disclosure, the protruding portion PRP may be spaced apart from the subsidiary area SBA or the bending area BA in a plan view.

According to the embodiment, the protruding portion PRP may include a protruding surface SMS and curved surfaces CUP1 and CUP2 in a plan view. At the end of the support layer 310, a protruding portion may be defined at the protruding surface SMS, while a concave portion may be defined at the curved surfaces CUP1 and CUP2. Here, the groove GRO is mainly located at the protruding surface SMS aligned with the bending area BA along the second direction DR2. The protruding surface SMS may protrude toward the bending area BA or the subsidiary area SBA of the display panel 100 and may be adjacent to the bending area BA or the subsidiary area SBA. The protruding surface SMS may be formed as a straight line parallel to the first direction DR1.

The curved surfaces CUP1 and CUP2 may be extended from the opposite sides of the protruding surface SMS to the support layer 310, respectively. The curved surfaces CUP1 and CUP2 may include a first curved surface CUP1 on one side of the protruding surface SMS, and a second curved surface CUP2 on the opposite side. Each of the first curved surface CUP1 and the second curved surface CUP2 may be concave or recessed from the protruding surface SMS, in a direction towards the display area DA. The protruding surface SMS may be an edge of the support layer 310 which is furthest from the display area DA, that is, closest to the bending area BA or the subsidiary area SBA.

The first curved surface CUP1 and the second curved surface CUP2 may have a rounded shape, and may be formed symmetrically with respect to an arbitrary line extended in the second direction DR2. For example, the curved surfaces may be symmetrically with respect to a center line of the display panel 100 or another virtual line located along the first direction DR1, such lines extended in the second direction DR2. In an embodiment, a protruding surface SMS is extended in a straight line, and curved surfaces (e.g., CUP1 and CUP2) are extended in a rounded shape from opposite sides of the protruding surface SMS and towards the display area DA.

A bending start line BSL as a virtual line where the bending area BA begins may be located at the boundary between the non-display area NDA and the subsidiary area SBA of the display panel 100. The bending start line BSL may be a portion where the bending of the display panel 100 begins, for example, a portion where the bending of the bending area BA of the display panel 100 begins. In an embodiment, the protruding portion or the concave portion of the side of the support layer 310 is spaced apart from the bending start line BSL.

According to the embodiment, the protruding surface SMS of the protruding portion PRP of the support layer 310 may be spaced apart from the bending start line BSL of the display panel 100. For example, the protruding surface SMS of the protruding portion PRP of the support layer 310 may be located between the bending start line BSL of the display panel 100 and the display area DA of the display panel 100. In other words, the protruding surface SMS of the protruding portion PRP of the support layer 310 may be located closer to the display area DA of the display panel 100 than the bending start line BSL of the display panel 100.

If the protruding surface SMS of the protruding portion PRP of the support layer 310 is closer to the display area DA of the display panel 100 than the bending start line BSL of the display panel 100 is, the bending area BA of the display panel 100 can be normally bent from the bending start line BSL. If the protruding surface SMS of the protruding portion PRP of the support layer 310 protrudes beyond the bending start line BSL of the display panel 100 to the subsidiary area SBA, there may be a defect that the bending area BA of the display panel 100 is not bent from the bending start line BSL but is bent at the subsidiary area SBA where the support layer 310 is not positioned. Accordingly, in the display device 10 according to the embodiment, the protruding surface SMS of the protruding portion PRP of the support layer 310 is closer to the display area DA of the display panel 100 than the bending start line BSL of the display panel 100 is, so that the display panel 100 can be normally bent.

According to the embodiment, the distance d1 between the protruding surface SMS of the protruding portion PRP of the support layer 310 and the bending start line BSL of the display panel 100 may be less than the distance d2 between the protruding surface SMS of the protruding portion PRP of the support layer 310 and the display area DA of the display panel 100. In this instance, most of the non-display area NDA of the display panel 100 except for the planar area defined with the distance d1 is covered by the support layer 310, thereby protecting the non-display area NDA of the display panel 100 from external impacts, etc.

As described above, the display device 10 according to the embodiment has the advantages of allowing the display panel 100 to be normally bent and of protecting the non-display area NDA by arranging the protruding surface SMS of the protruding portion PRP of the support layer 310 closer to the display area DA of the display panel 100 than the bending start line BSL of the display panel 100 is.

Hereinafter, a display device 10 according to embodiments of the present disclosure will be described with reference to the other drawings. The elements identical to those described above with reference to FIGS. 11 to 14 will not be described to avoid redundancy. Description will focus on differences.

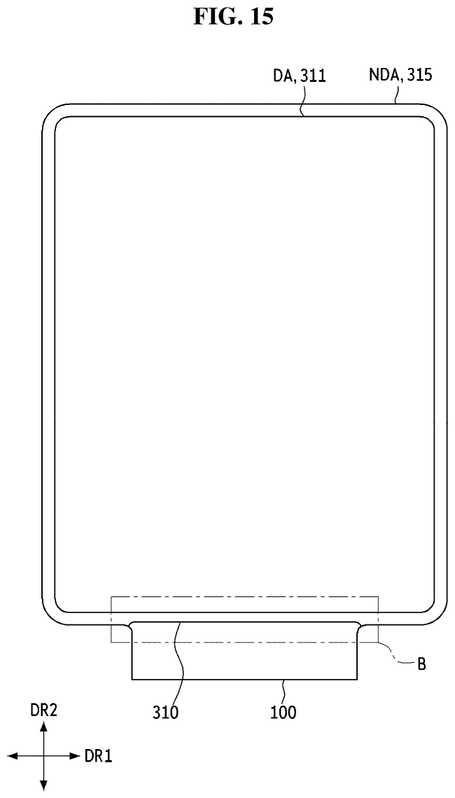

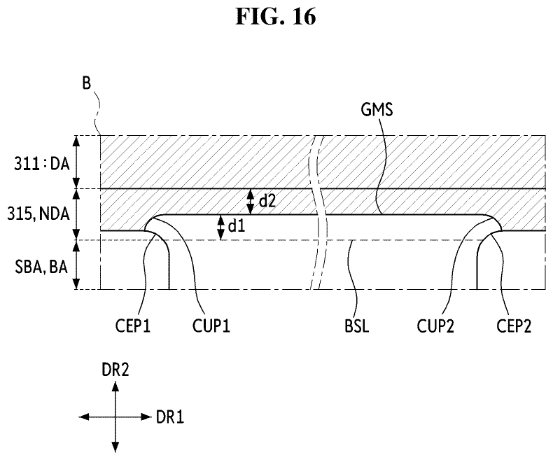

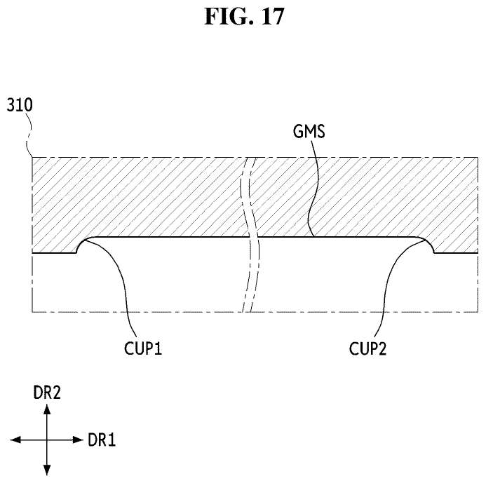

FIG. 15 is a plan view showing a support layer 310 of a display panel 100 of a display device 10 according to an embodiment of the present disclosure. FIG. 16 is an enlarged view of area B of FIG. 15. FIG. 17 is a view showing a groove GRO of the support layer according to the embodiment. It should be noted that FIGS. 15 and 16 show the rear side of the display panel coupled with the support layer.

Referring to FIGS. 15 to 17, the display device 10 according to the embodiment may include a display panel 100, and a support layer 310 coupled to the rear surface of the display panel 100.

The support layer 310 may include a groove GRO. The groove GRO may be a concave portion on one side of the support layer 310. The groove GRO may be concavely recessed in the non-display area NDA of the display panel 100 toward the display area DA. The groove GRO may be located in the non-display area NDA of the display panel 100 and is not extended beyond the display area DA, the bending area BA or the subsidiary area SBA. For example, the groove GRO may overlap with the non-display area NDA of the display panel 100 but not with the display area DA, the bending area BA or the subsidiary area SBA. According to the embodiment, the groove GRO may be spaced apart from the display area DA, the subsidiary area SBA and the bending area BA in a plan view.

According to the embodiment, the groove GRO may include a concave surface GMS and curved surfaces CUP1 and CUP2 in a plan view. At the end of the support layer 310, a protruding portion may be defined at the curved surfaces CUP1 and CUP2, while a concave portion may be defined at the concave surface GMS. Here, the groove GRO is mainly located at the concave surface GMS aligned with the bending area BA along the second direction DR2. The concave surface GMS may be recessed toward the display area DA away from the bending area BA or the subsidiary area SBA of the display panel 100, and may be adjacent to the display area DA. The concave surface GMS may be formed as a straight line parallel to the first direction DR1. In an embodiment, the concave surface GMS is extended in a straight line, and curved surfaces (e.g., CUP1 and CUP2) are extended in a rounded shape from opposite sides of the concave surface GMS and towards the bending area BA.

The curved surfaces CUP1 and CUP2 may be extended from the opposite sides of the concave surface GMS to the support layer 310. The curved surfaces CUP1 and CUP2 may include a first curved surface CUP1 on one side of the concave surface GMS, and a second curved surface CUP2 on the opposite side. The first curved surface CUP1 and the second curved surface CUP2 may have a rounded shape, and may be formed symmetrically with respect to an arbitrary line extended in the second direction DR2.

According to the embodiment, the concave surface GMS of the groove GRO of the support layer 310 may be spaced apart from the bending start line BSL of the display panel 100. For example, the concave surface GMS of the groove GRO of the support layer 310 may be located between the bending start line BSL of the display panel 100 and the display area DA of the display panel 100. In other words, the concave surface GMS of the groove GRO of the support layer 310 may be located closer to the display area DA of the display panel 100 than the bending start line BSL of the display panel 100.

If the concave surface GMS of the groove GRO of the support layer 310 is closer to the display area DA of the display panel 100 than the bending start line BSL of the display panel 100 is, the bending area BA of the display panel 100 can be normally bent from the bending start line BSL. If the concave surface GMS of the groove GRO of the support layer 310 is located beyond the bending start line BSL of the display panel 100 to the subsidiary area SBA, there may be a defect that the bending area BA of the display panel 100 is not bent from the bending start line BSL but is bent at the subsidiary area SBA where the support layer 310 is not positioned. Accordingly, in the display device 10 according to the embodiment, the concave surface GMS of the groove GRO of the support layer 310 is closer to the display area DA of the display panel 100 than the bending start line BSL of the display panel 100 is, so that the display panel 100 can be normally bent.

According to the embodiment of the present disclosure, the display panel 100 may include connecting surfaces CEP1 and CEP2 connecting the non-display area NDA with the subsidiary area SBA of the display panel 100. The connecting surfaces CEP1 and CEP2 may include a first connecting surface CEP1 located on one side and a second connecting surface CEP2 located on the opposite side. The first connecting surface CEP1 and the second connecting surface CEP2 may have a rounded shape, and may be formed symmetrically with respect to an arbitrary line extended in the second direction DR2. The first connecting surface CEP1 and the second connecting surface CEP2 may be extended across the non-display area NDA and the subsidiary area SBA of the display panel 100.

According to the embodiment, the curved surfaces CUP1 and CUP2 of the groove GRO of the support layer 310 and the connecting surfaces CEP1 and CEP2 of the display panel 100 may be connected with each other in a plan view. Specifically, one end of the first curved surface CUP1 of the groove GRO may be connected to the concave surface GMS, and the other end may be connected to (or meet) the first connecting surface CEP1 of the display panel 100. In addition, one end of the second curved surface CUP2 of the groove GRO may be connected to the concave surface GMS, and the other end may be connected to (or meet) the second connecting surface CEP2 of the display panel 100.

According to the embodiment, the distance d1 between the concave surface GMS of the groove GRO of the support layer 310 and the bending start line BSL of the display panel 100 may be greater than the distance d2 between the concave surface GMS of the groove GRO of the support layer 310 and the display area DA of the display panel 100. In this instance, a process tolerance can be obtained as the support layer 310 is spaced apart from the bending start line BSL of the display panel 100, to allow the display panel 100 to be bent normally.

As described above, the display device 10 according to the embodiment has the advantage of allowing the display panel 100 to be bent normally by arranging the concave surface GMS of the groove GRO of the support layer 310 closer to the display area DA of the display panel 100 than the bending start line BSL of the display panel 100 is.

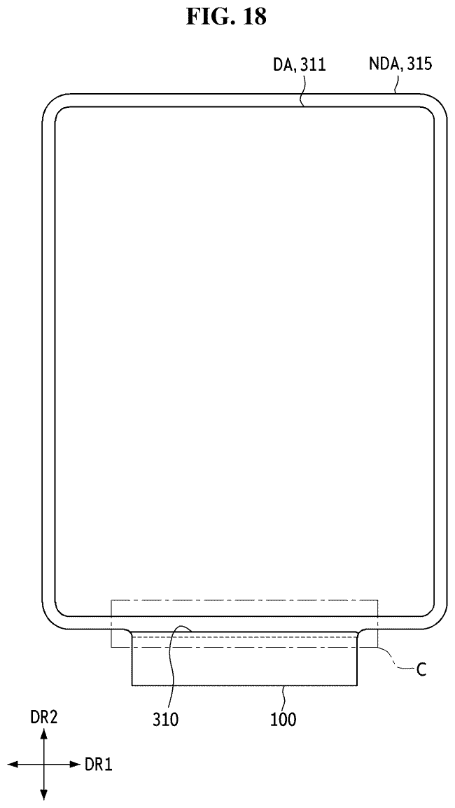

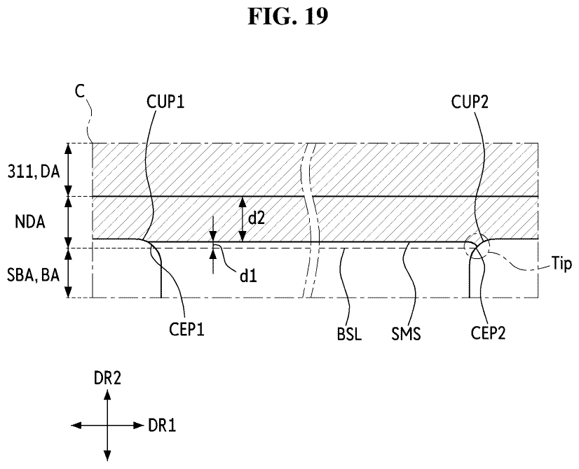

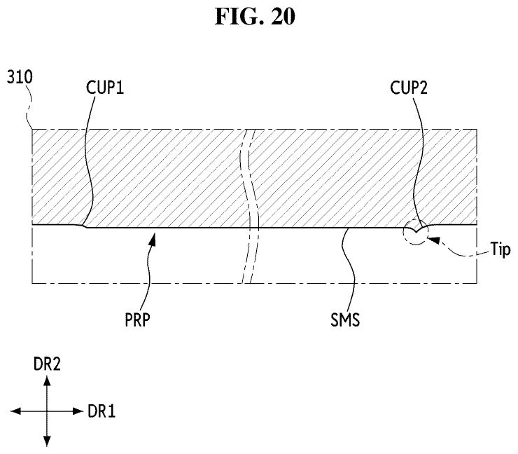

FIG. 18 is a plan view showing a display panel 100 and a support layer 310 of a display device 10 according to an embodiment of the present disclosure. FIG. 19 is an enlarged view of area C of FIG. 18. FIG. 20 is a view showing a protruding portion PRP of the support layer 310 according to the embodiment. It should be noted that FIGS. 18 and 19 show the rear side of the display panel 100 coupled with the support layer 310.

Referring to FIGS. 18 to 20, the display device 10 according to the embodiment may include a display panel 100, and a support layer 310 coupled to the rear surface of the display panel 100.

The display panel 100 may include a display area DA, a non-display area NDA surrounding the display area DA, and a subsidiary area SBA protruding out of the non-display area NDA.

The support layer 310 may include a protruding portion PRP. The protruding portion PRP may include a protruding surface SMS, a first curved surface CUP1, and a second curved surface CUP2 in a plan view. The protruding surface SMS of the protruding portion PRP of the support layer 310 may be spaced apart from the bending start line BSL of the display panel 100. The display panel 100 may include a first connecting surface CEP1 and a second connecting surface CEP2 connecting the non-display area NDA with the subsidiary area SBA of the display panel 100.

According to the embodiment, the protruding portion PRP of the support layer 310 may include a tip. The tip may be a portion which protrudes from the protruding portion PRP toward the bending area BA or the subsidiary area SBA in a plan view. The tip may protrude from the protruding portion PRP toward the bending area BA or the subsidiary area SBA. The tip may be located in the non-display area NDA of the display panel 100 and is not extended beyond the bending area BA or the subsidiary area SBA. A distal end of the tip may meet the bending start line BSL as a virtual line where the bending area BA begins (e.g., the boundary between the non-display area NDA and the subsidiary area SBA of the display panel 100), without being limited thereto. For example, the tip may overlap with the non-display area NDA of the display panel 100 but not with the bending area BA or the subsidiary area SBA. According to the embodiment, the tip of the protruding portion PRP may be spaced apart from the subsidiary area SBA or the bending area BA in a plan view. The tip may be located on one side of the protruding portion PRP along the first direction DR1.

According to the embodiment, the tip of the protruding portion PRP may be formed by extending the second curved surface CUP2 and the protruding surface SMS of the protruding portion PRP. For example, one surface of the tip may be formed by the second curved surface CUP2, and the other surface may be formed by the protruding surface SMS. At the end of the support layer 310, a protruding portion may be defined at the the protruding surface SMS and the tip. The tip may protrude further from the display area DA than the protruding surface SMS, such that an extension distance from the display area DA of consecutive protruding portions (e.g., SMS and tip) may increase toward a respective side along the first direction DR1. The curved surfaces CUP1 and CUP2 may be considered concave portion at opposing sides along the first direction DR1.

According to the embodiment, the distance d1 between the protruding surface SMS of the protruding portion PRP of the support layer 310 and the bending start line BSL of the display panel 100 may be less than the distance d2 between the protruding surface SMS of the protruding portion PRP of the support layer 310 and the display area DA of the display panel 100. In this instance, most of the non-display area NDA of the display panel 100 is covered by the support layer 310, thereby protecting the non-display area NDA of the display panel 100 from external impacts, etc.

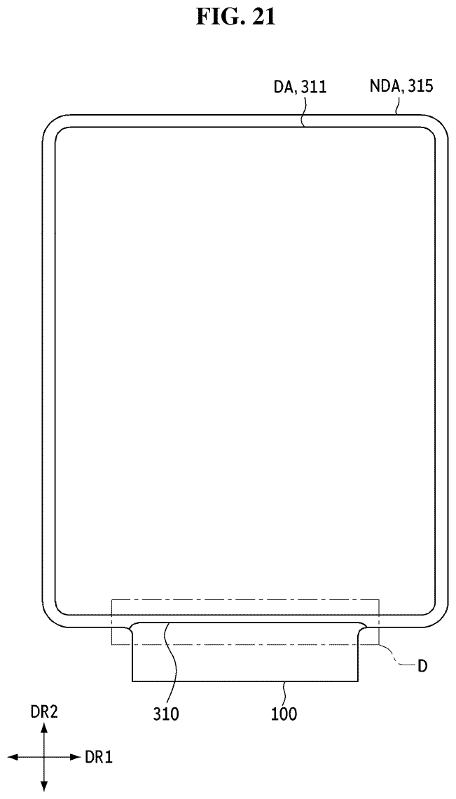

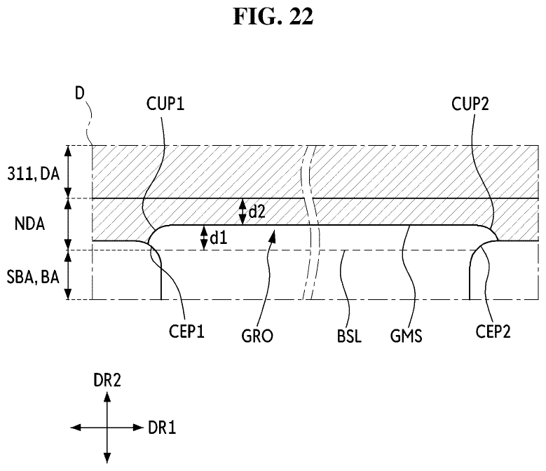

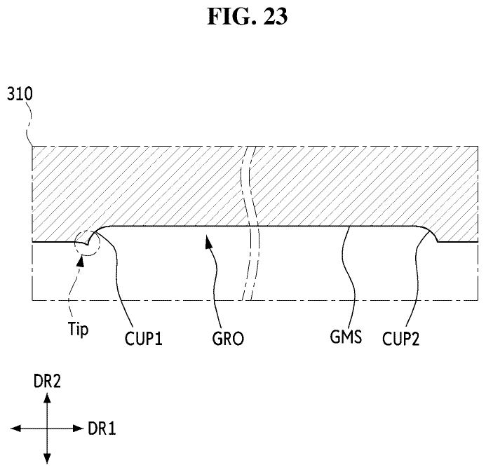

FIG. 21 is a plan view showing a display panel 100 and a support layer 310 of a display device 10 according to an embodiment of the present disclosure. FIG. 22 is an enlarged view of area D of FIG. 21. FIG. 23 is a view showing a groove GRO of the support layer 310 according to the embodiment. It should be noted that FIGS. 21 and 22 show the rear side of the display panel 100 coupled with the support layer 310.

Referring to FIGS. 21 to 23, the display device 10 according to the embodiment may include a display panel 100, and a support layer 310 coupled to the rear surface of the display panel 100.

The support layer 310 may include a groove GRO. The groove GRO may include a concave surface GMS, a first curved surface CUP1, and a second curved surface CUP2 in a plan view. The concave surface GMS of the groove GRO of the support layer 310 may be spaced apart from the bending start line BSL of the display panel 100. The display panel 100 may include a first connecting surface CEP1 and a second connecting surface CEP2 connecting the non-display area NDA with the subsidiary area SBA of the display panel 100.

According to the embodiment, in a plan view, the first curved surface CUP1 of the groove GRO of the support layer 310 may be connected to (or meet) the first connecting surface CEP1 of the display panel 100, and the second curved surface CUP2 of the groove GRO may be spaced apart from the second connecting surface CEP2 of the display panel 100 along the first direction DR1. Specifically, one end of the first curved surface CUP1 of the groove GRO may be connected to the concave surface GMS, and the other end may be connected to (or meet) the first connecting surface CEP1 of the display panel 100. One end of the second curved surface CUP2 of the groove GRO may be connected to the concave surface GMS, and the other end may be spaced apart from the second connecting surface CEP2 of the display panel 100 such as to meet the display panel at a non-curved surface of the display panel 100. For example, the second curved surface CUP2 may be connected to one side of the display panel 100 parallel to the concave surface GMS in a plan view.

The length of the first curved surface CUP1 of the groove GRO of the support layer 310 may different from the length of the second curved surface CUP2. For example, the length of the first curved surface CUP1 may be greater than the length of the second curved surface CUP2, such as in the first direction DR1. That is to say, the first curved surface CUP1 and the second curved surface CUP2 may be formed symmetrically with respect to an arbitrary line extended in the second direction DR2. Since the first curved surface CUP1 meets the edge of the display panel 100 along the first connecting surface CEP1 which is curved while the second curved surface CUP2 meets the edge of the display panel 100 at a position away from the curve of the second connecting surface CEP2, the support layer 310 may be protruded further at the first curved surface CUP1 than at the second curved surface CUP2. Here, the tip may define a location of the support layer 310 which is closest to the bending area BA.

According to the embodiment of the present disclosure, the groove GRO of the support layer 310 may include a tip. The tip may be a portion which protrudes from the groove GRO toward the bending area BA or the subsidiary area SBA in a plan view. The tip may protrude from the groove GRO toward the bending area BA or the subsidiary area SBA. The tip may be located in the non-display area NDA of the display panel 100 and is not extended beyond the bending area BA or the subsidiary area SBA. For example, the tip may overlap with the non-display area NDA of the display panel 100 but not with the bending area BA or the subsidiary area SBA. In an embodiment, the concave surface GMS may extend further than a curved surface among the curved surfaces (e.g., CUP1 and CUP2), in a direction towards the bending area BA, to define a tip protruding from the concave surface GMS toward the bending area BA. Here, the tip overlaps the non-display area NDA and does not overlap the bending area BA.

According to the embodiment, the tip of the groove GRO may be spaced apart from the subsidiary area SBA or the bending area BA in a plan view. The tip may be located on one side of the groove GRO. The tip may be closer to the subsidiary area SBA of the display panel 100 than the concave surface GMS of the groove GRO.

According to the embodiment, the distance d1 between the concave surface GMS of the groove GRO of the support layer 310 and the bending start line BSL of the display panel 100 may be greater than the distance d2 between the concave surface GMS of the groove GRO of the support layer 310 and the display area DA of the display panel 100. In this instance, a process tolerance can be obtained as the support layer 310 is spaced apart from the bending start line BSL of the display panel 100, to allow the display panel 100 to be bent normally.

Hereinafter, a method for fabricating (or providing) a display device 10 according to an embodiment of the present disclosure will be described with reference to the other drawings.

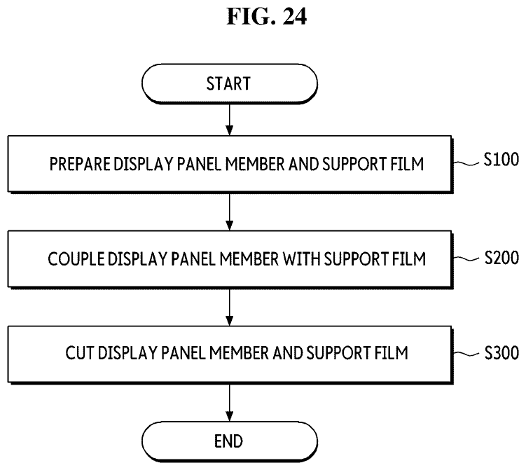

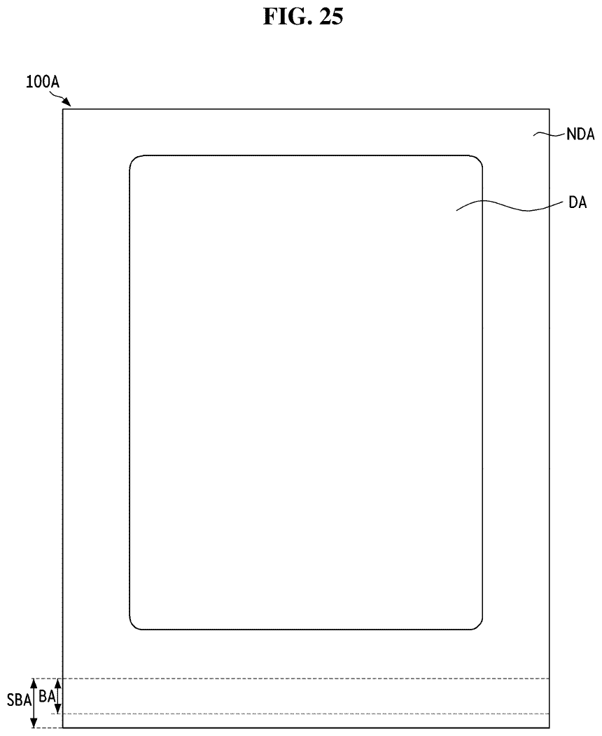

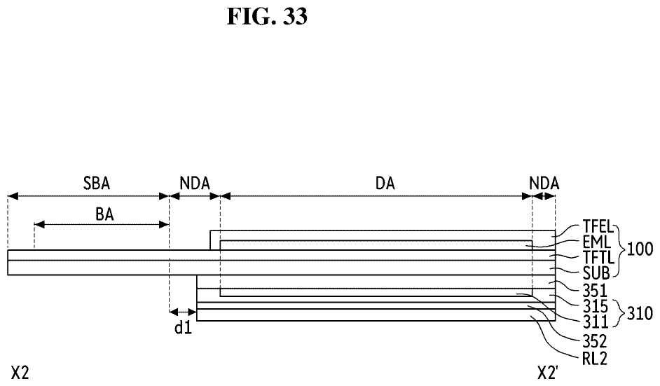

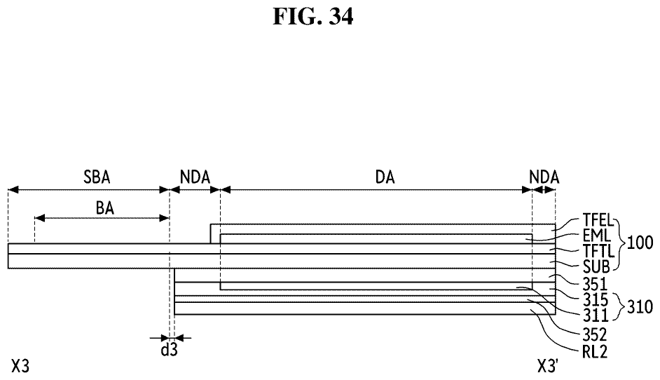

FIG. 24 is a flowchart for illustrating a method for fabricating a display device 10 according to an embodiment of the present disclosure. FIGS. 25 to 34 are views showing processing steps and structures of a method for fabricating a display device 10 according to an embodiment of the present disclosure. The display device 10 fabricated by the method shown in FIGS. 25 to 34 is one according to the embodiment of FIGS. 15 to 17, as an example.

Referring to FIG. 24, a method for fabricating a display device 10 according to an embodiment may include preparing a display panel member and a support film (S100), coupling the support film with the display panel member (S200), and cutting the display panel member and the support film (S300).

Hereinafter, a method for fabricating the display device of FIGS. 25 to 33 will be described in conjunction with FIG. 24.

Referring to FIGS. 25 to 28, a display panel member 100A as a preliminary display panel and a support film 400 as a preliminary support layer are prepared (S100).

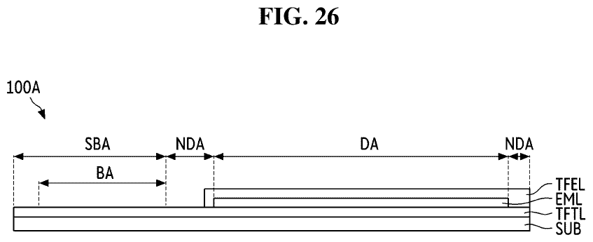

As shown in FIGS. 25 and 26, the display panel member 100A may include a substrate SUB, a thin-film transistor layer TFTL, an emission material layer EML, and an encapsulation layer TFEL. The display panel member 100A may include a display area DA in which the emission material layer EML is arranged, a non-display area NDA adjacent to or surrounding the display area DA, and a subsidiary area SBA including a bending area BA.

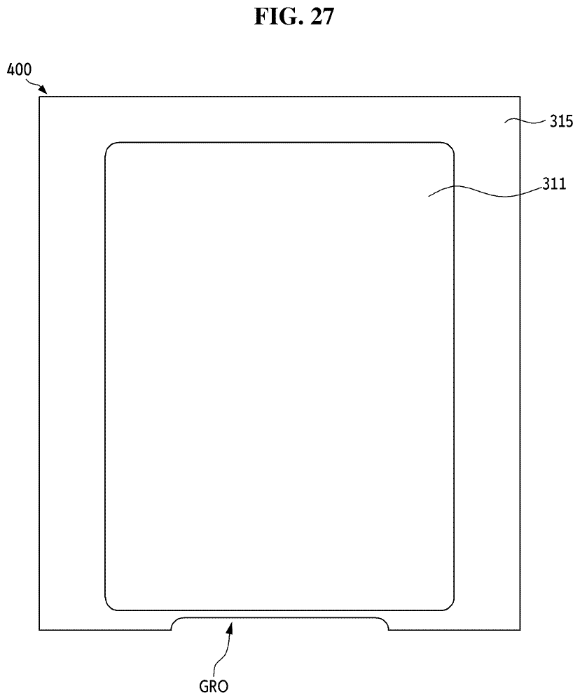

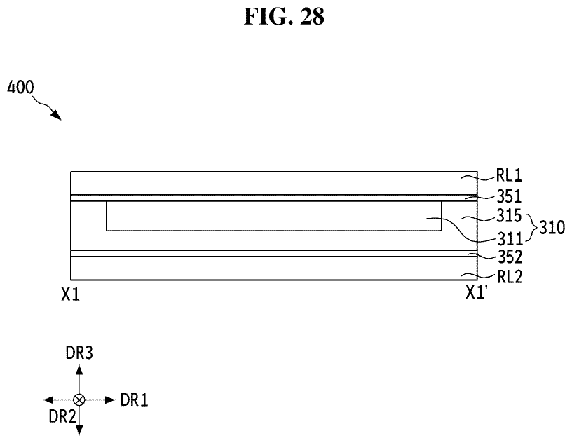

As shown in FIGS. 27 and 28, the support film 400 may include a preliminary stacked structure of a support layer 310, first and second coupling members 351 and 352, and first and second release films RL1 and RL2. The support layer 310 may include a structural layer 311 and a resin layer 315 which partially surrounds the structural layer 311. The support film 400 may include a groove GRO formed recessed from one side, for example, the lower side.

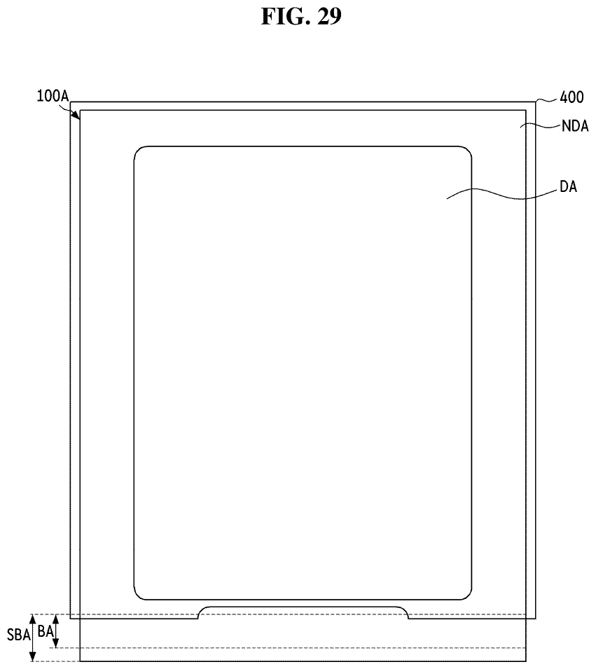

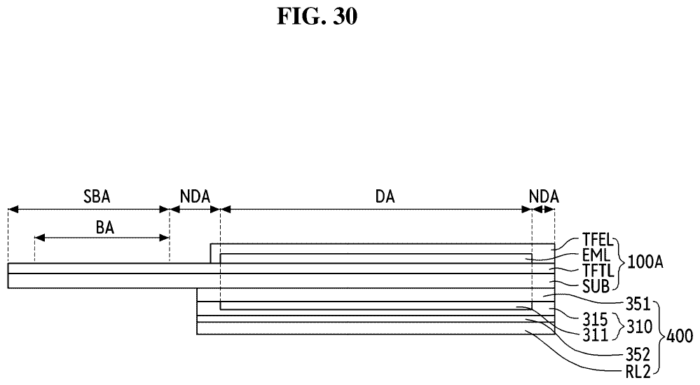

Subsequently, referring to FIGS. 29 and 30, the display panel member 100A and the support film 400 are coupled together (S200).

Initially, a first release film RL1 of the support film 400 is removed to expose a first coupling member 351. Then, the display panel member 100A and the support film 400 are coupled together such that the first coupling member 351 can be coupled to the display panel member 100A at the rear side of the display panel member 100A. In doing so, the display area DA of the display panel member 100A and the structural layer 311 of the support film 400 are aligned with each other along the thickness direction, and accordingly the structural layer 311 overlaps with the display area DA but not with the non-display area NDA. In addition, the groove GRO of the support film 400 may overlap with the non-display area NDA and the bending area BA of the display panel member 100A.

An end of the support film 400 may extend further than the non-display area NDA at a side of the display panel 100 at which the display panel 100 is bent. Other ends of the support film 400 may extend further than outermost edges of the display panel 100 as shown in FIG. 29.

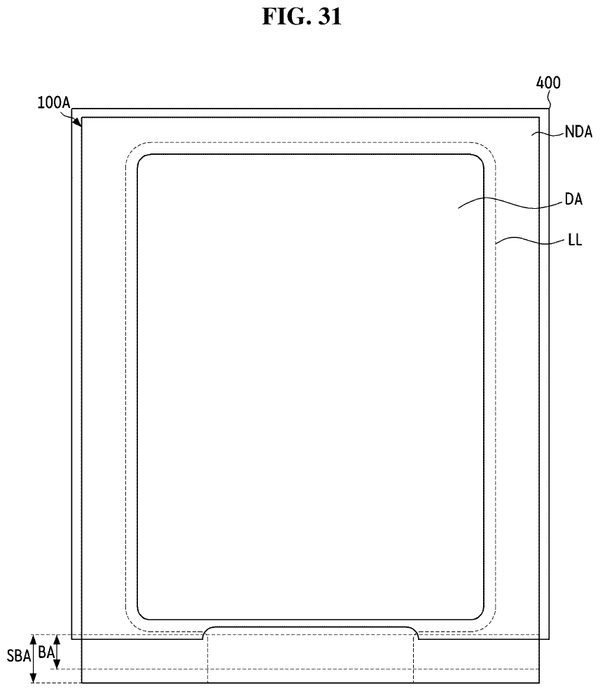

Subsequently, referring to FIGS. 31 to 33, a combined structure of the display panel member 100A and the support film 400 are cut (S300).

The cutting process may be carried out using a laser. For example, the display panel member 100A and the support film 400 may be cut using a laser trimming device. It should be understood, however, that the embodiments of the present disclosure are not limited thereto. A scriber, a water-jet cutter, an ultrasonic cutter, a plasma cutter, etc., may be employed.

The cutting process may be carried out by irradiating laser along a cutting line LL. The cutting line LL may be formed across the non-display area NDA and the subsidiary area SBA of the display panel member 100A. According to the embodiment, the cutting line LL passes through the opposite sides of the groove GRO of the support film 400, and is formed so that the portions of the support film 400 which protrude downward at the opposing the sides of the groove GRO can be cut. This is to protect the non-display area NDA on the opposite lower sides of the display area DA by the support film 400 without being exposed to the outside after cutting.

The cutting line LL may correspond to outer edges of the final display device 10. The cutting line LL is spaced apart from the bending start line BSL both at an area facing the bending area BA and an area not facing the bending area BA (e.g., an area at opposing ends of the groove GRO. At the outer edges formed by the cutting of the combined structure, end surfaces of the layers forming the combined structure may be aligned with each other, such as being coplanar with each other, without being limited thereto.

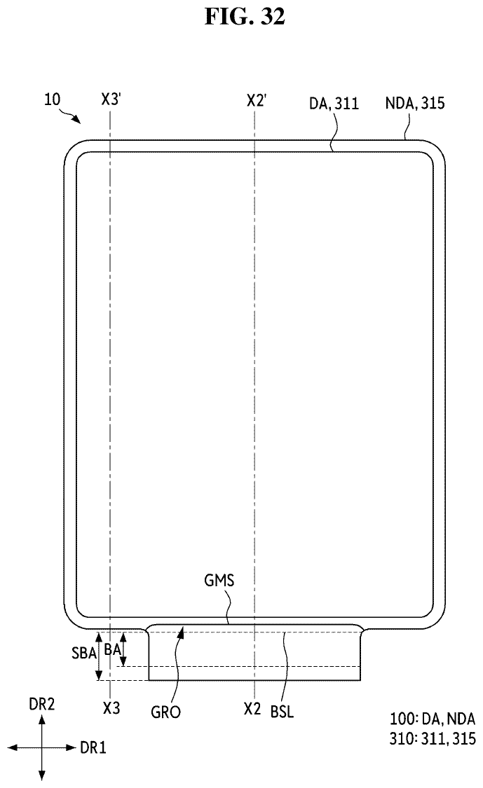

As shown in FIGS. 32 to 34, a display panel 100, a first coupling member 351, a support layer 310, a second coupling member 352 and a second release film RL2 which are separated from the preliminary stacked structure, may be fabricated by a cutting process.

The support layer 310 includes a groove GRO, and the groove GRO may include a concave surface GMS as a concave portion. The bending area BA of the display panel 100 may include a bending start line BSL. According to the embodiment, the concave surface GMS of the groove GRO of the support layer 310 may be spaced apart from the bending start line BSL of the bending area BA, in a direction toward the display area DA, in a plan view.

According to the embodiment of the present disclosure, the distance d1 between the concave surface GMS of the groove GRO of the support layer 310 and the bending start line BSL of the display panel 100 may be greater than the distance d3 between a side surface (e.g., an end surface) of the support layer 310 other than the concave surface GMS and the bending start line BSL of the display panel 100. In this instance, most of the non-display area NDA of the display panel 100 is covered by the support layer 310, thereby protecting the non-display area NDA of the display panel 100 from external impacts, etc.

According to an embodiment of the present disclosure, the distance d3 between the side surface of the support layer 310 other than the concave surface GMS and the bending start line BSL of the display panel 100 may be close to zero, and may be zero. It is to be understood that the distance d3 between the side surface of the support layer 310 other than the concave surface GMS and the bending start line BSL of the display panel 100 is zero means that the side surface of the support layer 310 other than the concave surface GMS coincides with the bending start line BSL of the display panel 100 such as meeting the bending start line BSL. That is, the support layer 310 is maximally spaced apart from the bending start line BSL at a location along the first direction DR1 which faces the bending area BA along the second direction DR2, and is minimally spaced apart from the bending start line BSL at a location along the first direction DR1 which does not face (or is adjacent to) the bending area BA along the second direction DR2.

Accordingly, the display device 10 according to the embodiment can be fabricated. Although not shown in the drawings, the second release film RL2 may be removed later to allow other layers like the cushion layer 320 to be coupled.

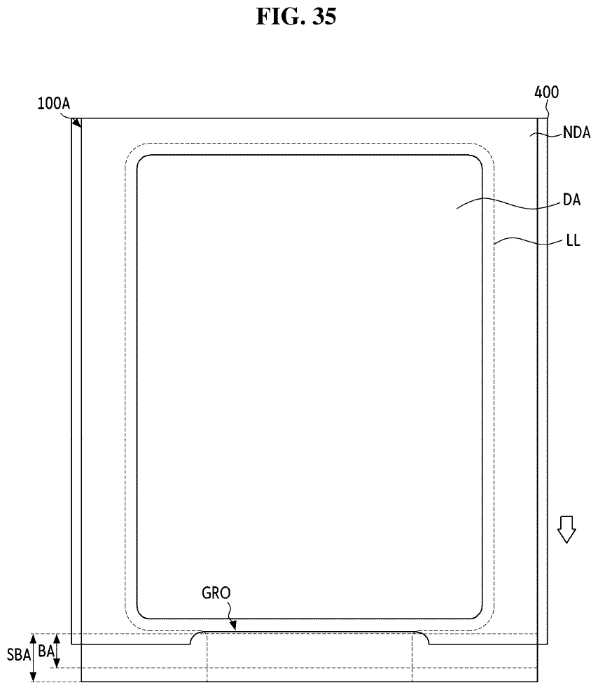

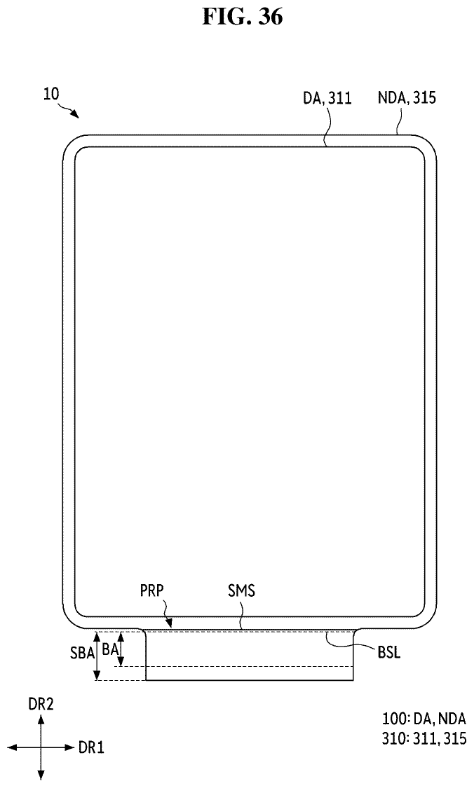

FIGS. 35 and 36 are views showing processing steps and structures of a method for fabricating a display device 10 according to an embodiment of the present disclosure. The display device 10 fabricated by the method shown in FIGS. 35 and 36 is one according to the embodiment of FIGS. 11 to 14, as an example.

The example shown in FIGS. 35 and 36 is identical to the example shown in FIGS. 29 to 33 except that a support film 400 is moved downward and coupled during a process of coupling a display panel member 100A with the support film 400.

Referring to FIGS. 35 and 36, the display panel member 100A and the support film 400 are coupled together such that the first coupling member 351 is coupled to the display panel member 100A at the rear side of the display panel member 100A. In doing so, the support film 400 may be moved downward relative to the display panel member 100A as indicated by the arrow in FIG. 35, and coupled with the display panel member 100A. In this instance, the support film 400 is moved downward to dispose a groove GRO of the support film 400 overlapping and extended across the bending area BA.

When the display panel member 100A and the support film 400 are cut along a cutting line LL, a protruding portion PRP may be formed at the support layer 310, as shown in FIG. 35. A protruding surface SMS of the protruding portion PRP may be spaced apart from the bending start line BSL of the bending area BA toward the display area DA in a plan view.

In an embodiment, a method of providing a display device includes preparing a display panel member 100A including a display area DA, a non-display area NDA and a bending area BA in order along a first direction (like DR2), preparing a support film 400 including a support layer 310 including a structural layer 311 and a resin layer 315 which surrounds the structural layer 311, a first release film RL1 on the support layer 310, a first coupling member 351 which is between the support layer 310 and the first release film RL1, and a protruding portion or a concave portion of the support film 400 defined by a side of the support film 400, removing the first release film RL1 from the support film 400, coupling the support film 400 to a rear surface of the display panel member 100A to provide the protruding portion or the concave portion of the support film 400 aligned with the bending area BA of the display panel member 100A, along the first direction (like DR2) (refer to FIG. 31, for example), and cutting the display panel member 100A and the support film 400 which are coupled to each other, along a cutting line LL corresponding to an outer edge of the display device 10, to form a display panel 100 and a support layer 310 of the display device 10 (refer to FIG. 32, for example). The cutting provides the protruding portion or the concave portion spaced apart from the bending area BA.

The methods for fabricating the display device 10 according to the embodiments of the present disclosure described above allow the protruding portion PRP or or the concave surface GMS at the groove GRO of the support layer 310 to be spaced apart from the bending area BA. Accordingly, there is an advantage in that the bending area BA of the display panel 100 can be normally bent at the bending start line BSL since the end of the support layer 310 is spaced apart from the bending area BA, at least at a location facing the bending area BA.

In addition, it is possible to prevent the non-display area NDA of the display panel 100 on the opposite sides of the protruding portion PRP at the groove GRO of the display support layer 310 from being exposed even if there is a process tolerance in attaching the display panel 100 to the support film 400. Accordingly, it is possible to address defects such as damage occurring if the support layer 310 is not placed in the non-display area NDA of the display panel 100.

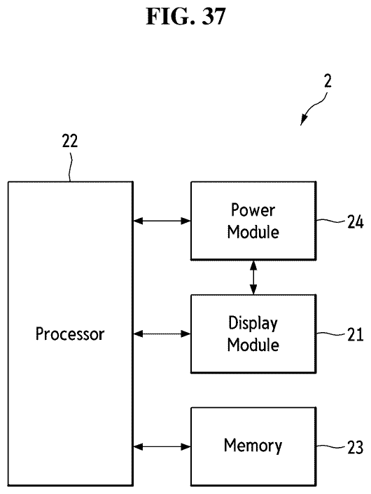

FIG. 37 is a block diagram of an electronic device 2 according to an embodiment of the present disclosure.

Referring to FIG. 37, an electronic device 2 according to an embodiment of the present disclosure may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), and a controller.

The memory 23 may store data information required for the operation of the processor 22 or the display module 21. When the processor 22 executes an application stored in the memory 23, an image data signal and/or an input control signal may be transmitted to the display module 21. The display module 21 may process the received signal and output image information through a display screen.

The power module 24 may include a power supply module such as a power adapter and a battery device, and a power conversion module which converts the power supplied by the power supply module to generate power required for the operation of the electronic device 2.

At least one of the elements of the electronic device 2 described above may be included in the display devices according to the embodiments described above. In addition, some of the individual modules functioning as a single module may be included in the display device 10 while some others may be provided separately from the display device 10. For example, the display device 10 may include the display module 21, and the processor 22, the memory 23 and the power module 24 may be implemented as other devices inside the electronic device 2 instead of the display device 10.

In an embodiment, an electronic device 2 includes the support layer 310 facing the display panel 100, a first coupling member which is between the display panel 100 and the support layer 310 and couples the display panel 100 to the support layer 310. A side of the support layer 310 overlaps the non-display area NDA which is between the display area DA and the bending area BA. A portion of the side of the support layer 310 which corresponds to the bending area BA defines a protruding portion or a concave portion which is spaced apart from the bending area BA. The electronic device 2 may further include a display device 10 for providing images, the display device 10 including the display panel 100, the support layer 310 and the first coupling member, and a processor for transmitting an image data signal to the display device 10.

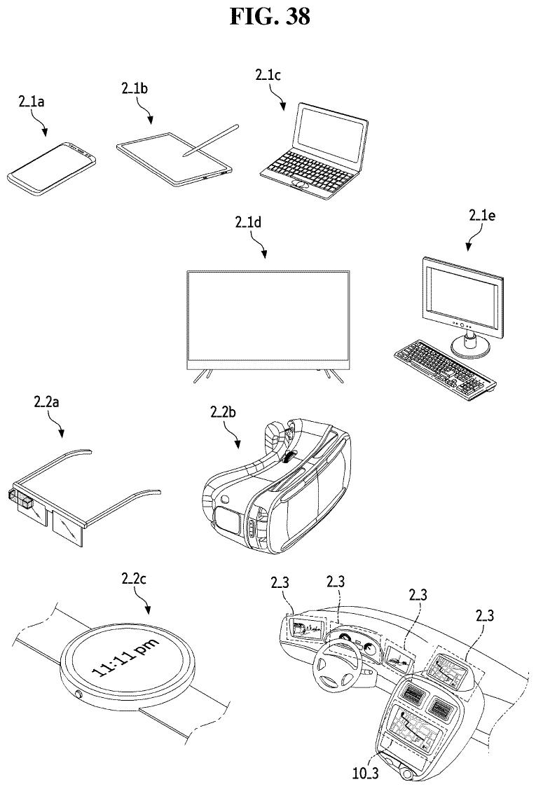

FIG. 38 is a view showing electronic devices according to a variety of embodiments of the present disclosure.

Referring to FIG. 38, a variety of electronic devices 2 employing the display devices according to the embodiments may include not only image display electronic devices such as a smart phone 2_1a, a tablet PC 2_1b, a laptop computer 2_1c, a television (TV) 2_1d and a desktop monitor 2_1e, but also wearable electronic devices including display modules such as smart glasses 2_2a, a head-mounted display 2_2b and a smart watch 2_2c, and electronic devices for vehicles 2_3 including display modules such as a center information display (CID) placed on the dashboard, the center fascia and the dashboard of a vehicle, and a room mirror display.

While the embodiments of the present disclosure have been described above with reference to the accompanying drawings, it will be understood by one of ordinary skill in the art that various modifications can be made without departing from the spirit or essential features of the invention. Therefore, the embodiments described above should be understood as illustrative rather than limiting in all respects.

What is claimed is:

1. A support film comprising:
a support layer attachable to a display device having a bending area extended from a display area, the support layer comprising:
a structural layer corresponding to the display area, and
a resin layer surrounding the structural layer;
a first release film on the support layer;
a first coupling member which is between the support layer and the first release film and configured to attach the support layer to the display device; and
a side of the support film defining a protruding portion or a concave portion,
wherein the support layer which is attached to the display device includes the side of the support film closest to the bending area together with the protruding portion or the concave portion spaced apart from the bending area.

2. The support film of claim 1, wherein the structural layer comprises a metal, ultra-thin glass or hybrid thin film glass.

3. The support film of claim 1, wherein the resin layer surrounds a lower surface and a side surface of the structural layer.

4. The support film of claim 1, wherein an upper surface of the structural layer and an upper surface of the resin layer are coplanar with each other.

5. The support film of claim 1, further comprising:
a second release film under the support layer; and
a second coupling member between the support layer and the second release film,
wherein
the protruding portion or the concave portion is defined in the resin layer, the first release film, the second release film, the first coupling member and the second coupling member, and
the protruding portion or the concave portion is spaced apart from the structural layer in a plan view.

6. The support film of claim 1, wherein
a portion of the resin layer overlaps the structural layer, and
a portion of the resin layer which does not overlap the structural layer is larger than a thickness of the structural layer.

7. An electronic device comprising:
a display panel comprising a display area, a bending area, and a non-display area between the display area and the bending area;
a support layer facing the display panel; and
a first coupling member which is between the display panel and the support layer and couples the display panel to the support layer,
wherein the support layer comprises:
a structural layer;
a resin layer surrounding the structural layer;
a side of the support layer overlaps the non-display area which is between the display area and the bending area; and
a portion of the side which corresponds to the bending area defining a protruding portion or a concave portion which is spaced apart from the bending area.

8. The electronic device of claim 7, wherein
the display panel comprises a bending start line at which bending of the bending area starts, and
the protruding portion or the concave portion of the side of the support layer is spaced apart from the bending start line.

9. The electronic device of claim 7, wherein the structural layer overlaps the display area and does not overlap the non-display area.

10. The electronic device of claim 7, wherein the resin layer does not overlap the bending area and overlaps each of the display area and the non-display area.

11. The electronic device of claim 8, wherein the protruding portion comprises:
a protruding surface extended in a straight line, and
curved surfaces extended in a rounded shape from opposite sides of the protruding surface and towards the display area.

12. The electronic device of claim 11, wherein
the protruding surface and the bending start line are parallel to each other, and
a distance between the protruding surface and the bending start line is smaller than a distance between the protruding surface and the display area.

13. The electronic device of claim 11, wherein
the protruding portion further comprises a tip protruding from the protruding surface and toward the bending area, and
the tip overlaps the non-display area and does not overlap the bending area.

14. The electronic device of claim 8, wherein the concave portion comprises:
a concave surface extended in a straight line, and
curved surfaces extended in a rounded shape from opposite sides of the concave surface and towards the bending area.

15. The electronic device of claim 14, wherein
the concave surface and the bending start line are parallel to each other, and
a distance between the concave surface and the bending start line is greater than a distance between the concave surface and the display area.

16. The electronic device of claim 14, wherein
the concave surface extends further than a curved surface among the curved surfaces, in a direction towards the bending area, to define a tip protruding from the concave surface toward the bending area, and
the tip overlaps the non-display area and does not overlap the bending area.

17. The electronic device of claim 16, wherein
the curved surfaces comprise a first curved surface extended from one side of the concave surface and a second curved surface extended from an opposite side of the concave surface, and
a length of the first curved surface is different from a length of the second curved surface.

18. The electronic device of claim 7, further comprising:
a display device for providing images, the display device including the display panel, the support layer and the first coupling member; and
a processor for transmitting an image data signal to the display device.

19. A method for providing a display device, the method comprising:
preparing a display panel member comprising a display area, a non-display area and a bending area in order along a first direction;
preparing a support film comprising:
a support layer comprising a structural layer and a resin layer which surrounds the structural layer;
a first release film on the support layer;
a first coupling member which is between the support layer and the first release film; and
a protruding portion or a concave portion of the support film defined by a side of the support film;
removing the first release film from the support film;
coupling the support film to a rear surface of the display panel member to provide the protruding portion or the concave portion of the support film aligned with the bending area of the display panel member, along the first direction; and
cutting the display panel member and the support film along a cutting line corresponding to an outer edge of the display device, to form a display panel and a support layer of the display device,
wherein the cutting provides the protruding portion or the concave portion spaced apart from the bending area.

20. The method of claim 19, wherein the coupling of the support film to the rear surface of the display panel member further provides the structural layer overlapping the display area and not overlapping the non-display area.
